(19) United States
(12) Patent Application Publication
(10) Pub. No.: US 2006/0084251 A1
(43) Pub. Date: Apr. 20, 2006

(54) Plating method, semiconductor device fabrication method and circuit board fabrication method

(75) Inventors: Kanae Nakagawa, Kawasaki (JP); Takeshi Shioga, Kawasaki (JP); Masataka Mizukoshi, Kawasaki (JP); Kazuaki Kurihara, Kawasaki (JP); John David Baniecki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/066,481

(22) Filed: Feb. 28, 2005

(30) Foreign Application Priority Data
Oct. 18, 2004 (JP) 2004-303345

(51) Int. Cl. H01L 21/20

(52) U.S. Cl. 438/584

(57) ABSTRACT

The plating method comprises the step of forming a resin layer 10 over a substrate 16; the step of cutting the surface part of the resin layer 10 so that the ten-point height of irregularities of the surface of the resin layer 10 is 0.5-5 μm; the step of forming a seed layer 36 on the resin layer 10; and the step of forming a plating film 44 on the seed layer 36 by electroplating. Suitable roughness can be give to the surface of the resin layer 10, whereby the adhesion between the seed layer 36 and the resin layer 10 can be sufficiently ensured. Excessively deep pores are not formed in the surface of the resin layer 10, as are by desmearing treatment, whereby a micronized pattern of a photoresist film 40 can be formed on the resin layer 10. Thus, interconnections 44, etc. can be formed over the resin layer 10 at a narrow pitch with high reliability ensured.

### CROSS-REFERENCE TO RELATED APPLICATION

This application is based upon and claims priority of Japanese Patent Application No. 2004-303345, filed on Oct. 18, 2004, the contents being incorporated herein by reference.

### BACKGROUND OF THE INVENTION

The present invention relates to a plating method, and a semiconductor fabrication method and a circuit board fabrication method using the plating method, more specifically, a plating method which can realize high reliability, and a semiconductor device fabrication method and a circuit board fabrication method using the plating method.

In the multi-layer interconnections formed on semiconductor substrates or circuit boards, inter-layer insulation films are required for the electric insulation between the interconnection layers.

In the steps of forming such inter-layer insulation films, recently the technique of forming an inter-layer insulation film by applying a sheet of a resin (hereinafter called a resin sheet) to a semiconductor substrate or a circuit board by vacuum press is noted. Forming an inter-layer insulation film of the resin sheet can much reduce the material waste in comparison with forming an inter-layer insulation film by spin coating, and resultantly inter-layer insulation films can be formed at lower costs.

In forming an interconnection on a resin layer formed by using such resin sheet, the interconnection can be formed by, e.g., the following technique.

First, contact holes are formed in the resin layer by a laser or others. Next, desmearing treatment is performed. The desmearing treatment is a chemical treatment for removing smears of the resin produced when the contact holes are formed in the resin layer by the laser or others. The desmearing treatment removes the smears out of the contact holes and forms convexities and concavities in the surface of the resin layer. In the desmearing treatment, the resin layer is immersed in, e.g., an alkaline solution of permanganic acid of 50-90° C. for about several minutes to several tens minutes. Then, a seed layer for forming a plating film is formed by electroless plating on the resin layer with the concavities and convexities formed in the surface by the desmearing treatment. The seed layer is formed, anchored in the concavities, i.e., a number of fine pores, formed in the surface of the resin layer, whereby the adhesion between the resin layer and the plating film is sufficiently secured. This phenomena is called anchor effect. Then, a photoresist film is formed on the entire surface of the resin layer, and openings are formed in the photoresist film by photolithography. Next, a plating film is formed on the seed layer in the openings by electroplating. Because of the sufficient adhesion between the seed layer and the resin layer, the plating film is secured to the resin layer via the seed layer. Finally, the photoresist film is released, and the interconnection is formed on the resin layer.

Patent Reference 1 discloses a method for forming a plating film on a resin substrate, in which a resin substrate layer with UV radiation applied to is immersed in an alkaline solution to subject the resin substrate to the desmearing treatment, whereby the adhesion between the resin substrate and the plating film is retained firmly.

Patent Reference 2 discloses a method for forming conductor circuit pattern on a molding formed by injection molding, in which when a resist applied to the surface of the injection molding, laser beams are applied also to the surface of the injection molding to thereby roughen the surface of the injection molding, whereby the step of roughening the surface of the injection molding can be omitted.

[Patent Reference 1]

Specification of Japanese Patent Application Unexamined Publication No. 2003-27250

[Patent Reference 2]

Specification of Japanese Patent Application Unexamined Publication No. Hei 11-6073

As disclosed in Patent Reference 1, when an object (the resin substrate) for the plating film to be formed on is immersed in an alkaline solution to thereby make the desmearing treatment, deep pores of several μm to ten-odd μm are formed in the surface of the resin layer, which makes it difficult to form a micronized interconnection pattern on the surface of the resin substrate by using a photoresist film. When the pitch of the interconnections formed on the resin substrate is small, the possibility that short circuits, etc. may take place is higher.

As disclosed in Patent Reference 2, when the surface of an object (the resin substrate) for the plating film to be formed on is roughened by applying laser beams, the application of laser beams takes a long time when the surface for the plating film to be formed on is large.

### SUMMARY OF THE INVENTION

An object of the present invention is to provide a plating method which can easily form a plating film of good adhesion without making the desmearing treatment on a resin layer over a large area of which the plating film is to be formed, and a semiconductor device fabrication method and a circuit board fabrication method using the plating method.

According to one aspect of the present invention, there is provided a plating method comprising the steps of: forming a resin layer over a base substrate; cutting the surface part of the resin layer with a cutting tool so that a ten-point height of irregularities of the surface of the resin layer is 0.5-5 μm; forming a seed layer on the resin layer; and forming a plating film on the seed layer by electroplating.

According to another aspect of the present invention, there is provided a semiconductor device fabrication method comprising the steps of: forming a resin layer over a semiconductor substrate; cutting the surface part of the resin layer with a cutting tool so that a ten-point height of irregularities of the surface of the resin layer is 0.5-5 μm; forming a seed layer on the resin layer; and forming on the seed layer an interconnection of a plating film by electroplating.

According to further another aspect of the present invention, there is provided a circuit board fabrication method comprising the steps of: forming a resin layer over a base substrate; cutting the surface part of the resin layer with a cutting tool so that a ten-point height of irregularities of the surface of the resin layer is 0.5-5 μm; forming a seed layer on the resin layer; and forming an interconnection on the seed layer by electroplating.

According to further another aspect of the present invention, there is provided a circuit board fabrication method for fabricating a circuit board including a base substrate; and a capacitor having a lower electrode formed over the base substrate, a dielectric film formed over the lower electrode, and an upper electrode formed over the dielectric film, the method comprising the steps of: forming the lower electrode over the base substrate; forming the dielectric film containing a resin over at least the lower electrode; cutting with a cutting tool the surface part of the dielectric film so that a ten-point height of irregularities of the surface of the dielectric film is 0.5-5 μm; forming a seed layer on the dielectric film; and forming the upper electrode on the seed layer by electroplating.

According to further another aspect of the present invention, there is provided a circuit board fabrication method for fabricating a circuit board including a base substrate; a first electrode formed over the base substrate; and a resistor formed over the first electrode; and a second electrode formed over the resistor, the method comprising the steps of: forming the first electrode on the base substrate; forming a resistor layer containing the resin over the first electrode; cutting the surface part of the resistor layer so that a ten-point height of irregularities of the surface of the resistor layer is 0.5-5 μm; forming a seed layer on the resistor layer; and forming an electrode on the seed layer by electroplating.

According to further another aspect of the present invention, there is provided a circuit board fabrication method for fabricating a circuit board including a base substrate and an inductor formed over the base substrate, the method comprising the steps of: forming an insulation layer containing a resin over the base substrate; cutting the surface part of the insulation layer with a cutting tool so that a ten-point height of irregularities of the surface of the insulation layer is 0.5-5 μm; forming a seed layer on the insulation layer, and forming the inductor on the seed layer by electroplating.

According to the present invention, as a pre-processing for forming the seed layer for the plating processing, the surface of the resin layer is cut with a cutting cutting tool so as to give the surface of the resin layer suitable roughness. Such processing sufficiently and easily ensures the adhesion between the resin layer and the seed layer. According to the present invention, no excessively deep pores are formed in the surface of the resin layer, as are formed by the desmearing treatment, which permits a micronized pattern to be formed on the resin layer. According to the present invention, the surface roughening processing is made over a large area in a short period of time, which makes it possible to form a micronized pattern to be formed over a large area in a short period of time. Thus, according to the present invention, interconnections, etc. can be easily formed on the resin layer at an extremely small pitch while ensuring high reliability.

According to the present invention, the dielectric film of the capacitor is formed of a resin sheet, and the surface of the dielectric film is cut with a cutting tool. This processing can suitably adjust the roughness of the surface of the dielectric film of a resin, whereby the adhesion between the dielectric film and the upper electrodes can be sufficiently ensured. According to the present invention, the desmearing treatment is not necessary, and no excessively deep pores are formed in the surface of the dielectric film. Thus, even when the thickness of the dielectric film is made sufficiently small, the insulation between the upper electrodes and the lower electrodes can be sufficiently ensured. The present invention can provide a circuit board having high reliability and capacitors of a large dielectric capacity.

In the present invention, the surface of the resistor layer of a resin is cut with a cutting tool, which gives the surface of the resistor layer of a resin suitable roughness. Thus, the adhesion between the resistor layer and the electrodes can be sufficiently ensured. The present invention does not require the desmearing treatment, and accordingly no excessively deep pores are formed in the surface of the resistor layer of the resin. Accordingly, even when the thickness of the resistor layer is made small, the inter-electrode insulation can be sufficiently ensured. Thus, the thickness of the resistor layer is suitable set, whereby the resistor value can be set at a required valued. Without excessively deep pores formed in the surface of the resistor layer, the dispersion of the resistor value can be made small. The present invention can fabricate a circuit board including resistors of high reliability.

In the present invention, the surface of the high-magnetic permeability layer of a resin film is cut with a cutting tool, whereby suitable roughness can be given to the surface of the high-magnetic permeability of the resin film. Accordingly, the adhesion between the high-magnetic permeability layer of a resin and the inductor can be sufficiently ensured. The present invention does not require the desmearing treatment, and accordingly no excessively deep pores are formed in the surface of the high-magnetic permeability layer of the resin, which allows a micronized pattern of a photoresist film to be formed on the high-magnetic permeability layer. Thus, according to the present invention, an inductor of high reliability can be formed at an extremely small coil pitch.

### BRIEF DESCRIPTION OF THE DRAWINGS

FIGS. 1A and 1B are side views of a resin layer when a surface part of the resin layer is cut with a cutting tool.

FIGS. 2A and 2B are views of a semiconductor device in the steps of the semiconductor fabrication method according to a first embodiment of the present invention, which illustrate the method (Part 1).

FIGS. 3A and 3B are views of the semiconductor device in the steps of the semiconductor fabrication method according to the first embodiment of the present invention, which illustrate the method (Part 2).

FIGS. 4A and 4B are views of the semiconductor device in the steps of the semiconductor fabrication method according to the first embodiment of the present invention, which illustrate the method (Part 3).

FIGS. 5A and 5B are views of the semiconductor device in the steps of the semiconductor fabrication method according to the first embodiment of the present invention, which illustrate the method (Part 4).

FIGS. 6A and 6B are views of the semiconductor device in the steps of the semiconductor fabrication method according to the first embodiment of the present invention, which illustrate the method (Part 5).

FIGS. 7A and 7B are views of the semiconductor device in the steps of the semiconductor fabrication method according to the first embodiment of the present invention, which illustrate the method (Part 6).

FIGS. 8A to 8C are views of the semiconductor device in the steps of the semiconductor fabrication method according to the first embodiment of the present invention, which illustrate the method (Part 7).

FIGS. 9A and 9B are views of the semiconductor device in the steps of the semiconductor fabrication method according to the first embodiment of the present invention, which illustrate the method (Part 8).

FIGS. 10A and 10B are views of the semiconductor device in the steps of the semiconductor fabrication method according to the first embodiment of the present invention, which illustrate the method (Part 9).

FIGS. 11A and 11B are views of the semiconductor device in the steps of the semiconductor fabrication method according to the first embodiment of the present invention, which illustrate the method (Part 10).

FIGS. 12A and 12B are views of the semiconductor device in the steps of the semiconductor fabrication method according to the first embodiment of the present invention, which illustrate the method (Part 11).

FIGS. 13A and 13B are views of the resin film having a matrix of epoxy resin containing a rubber-based filler, which is cut with the cutting tool.

FIGS. 14A and 14B are views of a circuit board in the steps of the circuit board fabrication method according to a second embodiment of the present invention, which illustrate the method (Part 1).

FIGS. 15A and 15B are views of the circuit board in the steps of the circuit board fabrication method according to the second embodiment of the present invention, which illustrate the method (Part 2).

FIGS. 16A and 16B are views of the circuit board in the steps of the circuit board fabrication method according to the second embodiment of the present invention, which illustrate the method (Part 3).

FIG. 17 is a view of the circuit board in the step of the circuit board fabrication method according to the second embodiment of the present invention, which illustrates the method (Part 4).

FIGS. 18A and 18B are views of the circuit board in the steps of the circuit board fabrication method according to the second embodiment of the present invention, which illustrate the method (Part 5).

FIGS. 19A and 19B are views of the circuit board in the steps of the circuit board fabrication method according to the second embodiment of the present invention, which illustrate the method (Part 6).

FIGS. 20A and 20B are views of the circuit board in the steps of the circuit board fabrication method according to the second embodiment of the present invention, which illustrate the method (Part 7).

FIGS. 21A and 21B are views of the circuit board in the steps of the circuit board fabrication method according to the second embodiment of the present invention, which illustrate the method (Part 8).

FIGS. 22A and 22B are views of the circuit board in the steps of the circuit board fabrication method according to the second embodiment of the present invention, which illustrate the method (Part 9).

FIG. 23 is a view of the circuit board in the step of the circuit board fabrication method according to the second embodiment of the present invention, which illustrates the method (Part 10).

FIGS. 24A and 24B are views of a circuit board in the steps of the circuit board fabrication method according to a third embodiment of the present invention, which illustrate the method (Part 1).

FIGS. 25A and 25B are views of a circuit board in the steps of the circuit board fabrication method according to a third embodiment of the present invention, which illustrate the method (Part 2).

FIGS. 26A and 26B are views of a circuit board in the steps of the circuit board fabrication method according to a fourth embodiment of the present invention, which illustrate the method (Part 1).

FIGS. 27A and 27B are views of the circuit board in the steps of the circuit board fabrication method according to the fourth embodiment of the present invention, which illustrate the method (Part 2).

FIG. 28 is views of the circuit board in the steps of the circuit board fabrication method according to the fourth embodiment of the present invention, which illustrate the method (Part 3).

### DETAILED DESCRIPTION OF THE INVENTION

The inventors of the present application made earnest studies to solve the above-described problems and have got the idea that the surface part of a resin layer is cut by a cutting tool of diamond to thereby give the surface of the resin layer a suitable roughness without making the desmearing treatment.

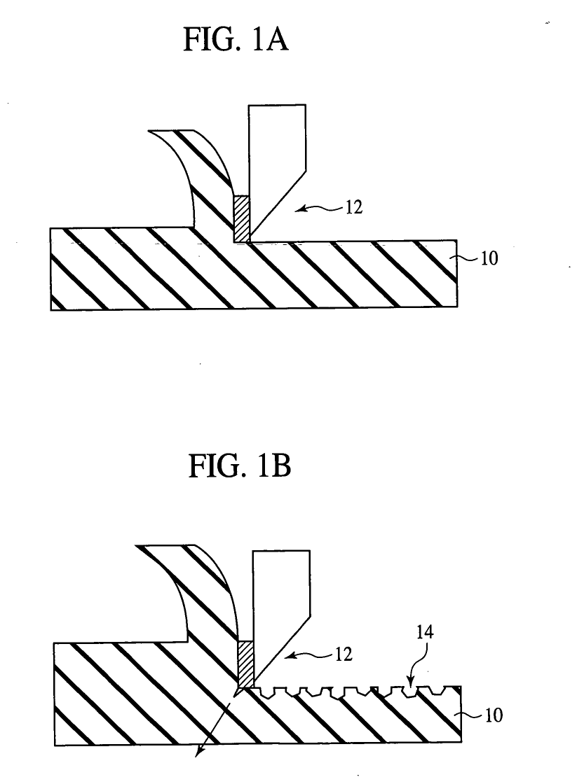

FIGS. 1A and 1B are side views of a resin layer when a surface part of the resin layer is cut with a cutting tool.

As illustrated in FIG. 1A, when the surface of a resin layer (a resin film before cut) 10 is cut in a relatively small cut amount with a cutting tool 12, the force applied to the cut surface is relatively small, and the roughness in the surface of the resin layer 10 is very small. The cut amount is a depth of one cut by the cutting tool.

In contrast to this, as illustrated in FIG. 1B, the surface of the resin layer 10 is cut in a relatively large cut amount, the force applied to the cut surface is relatively large, and concavities and convexities 14 of a suitable roughness are formed in the surface of the resin layer 10.

As described above, cut conditions are suitably set by the cutting tool 12, whereby a suitable roughness can be given to the surface of the resin layer 10. This makes it possible to form a plating film of good adhesion on the resin layer 10 without the desmearing treatment. Furthermore, the cut of the surface of the resin layer 10 with the cutting tool 12 does not form in the surface of the resin layer 10 pores which are so deep as those formed by making the desmearing treatment on the surface of the resin layer 10, which permits a micronized pattern of a photoresist film to be formed on the resin layer 10. Thus, according to the present invention, interconnections of the plating film can be formed at small pitches.

### A FIRST EMBODIMENT

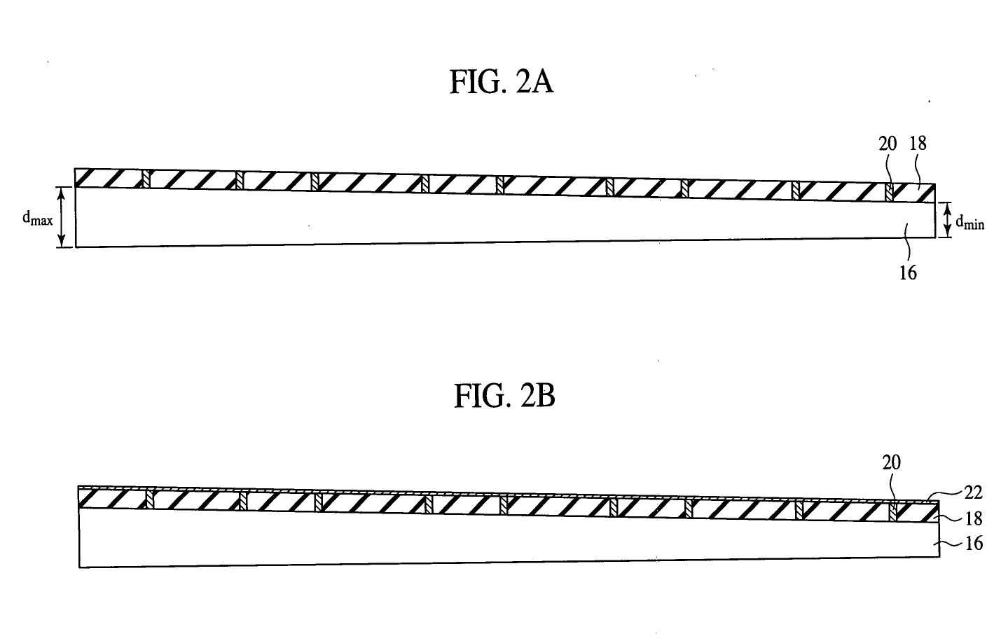

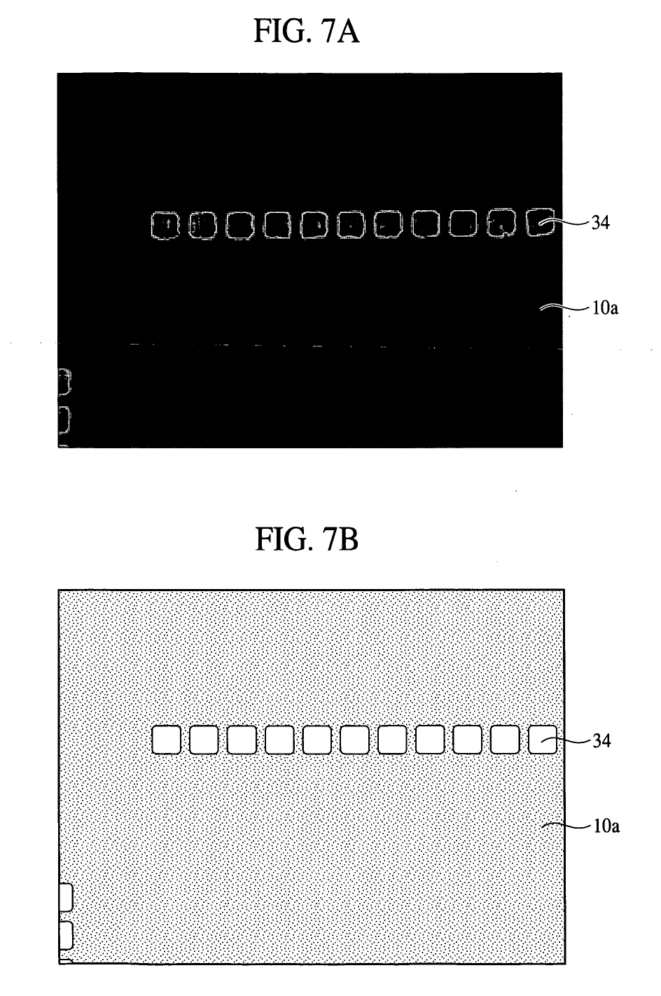

The plating method according to a first embodiment of the present invention and the semiconductor device fabrication method using the plating method will be explained with reference to FIGS. 2A to 13B. FIGS. 2A to 12B are sectional views of a semiconductor device in the steps of the semiconductor device fabrication method according to the present embodiment, which illustrate the fabrication method. FIGS. 2A to 6B and 8A to 12B are sectional views, and FIGS. 7A and 7B are plan views.

As illustrated in FIG. 2A, a semiconductor substrate 16 is prepared. The semiconductor substrate 16 is, e.g., a silicon wafer. Transistors (not illustrated), etc. are formed on the semiconductor substrate 16. On the semiconductor substrate 16 with the transistors formed on, an inter-layer insulation film 18 of, e.g., a silicon oxide film is formed. The inter-layer insulation film 18 is formed by, e.g., CVD. A plurality of the inter-layer insulation film 18 are formed on the semiconductor substrate 16, but one of the inter-layer insulation films is illustrated in FIG. 2A. Conductor plugs 20 are buried in the inter-layer insulation film 18. The conductor plugs 20 are electrically connected to, e.g., the source/drain diffused layer (not illustrated), the gate electrodes (not illustrated), etc. of the transistors.

The TTV (Total Thickness Variation) of the semiconductor substrate 16 is, e.g., 5 μm. A TTV means flatness of a wafer and a difference between a maximum value dmax and a minimum value dmin of the thickness of the entire wafer surface.

Next, as illustrated in FIG. 2B, a 500 nm-thickness seed layer 22 of copper or nickel is formed on the entire surface by, e.g., sputtering.

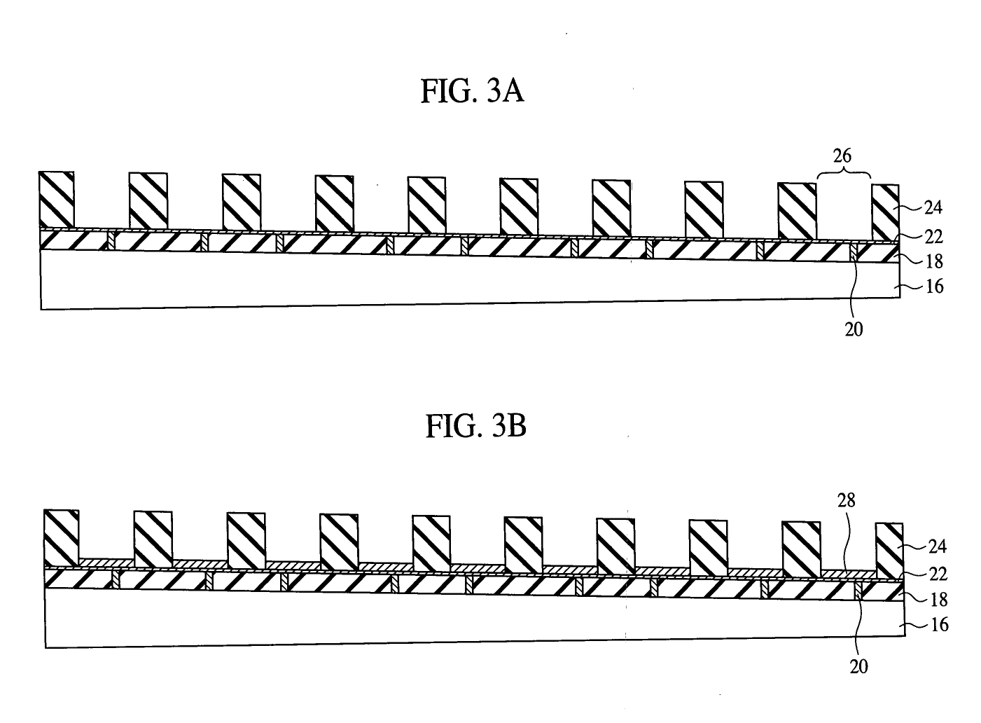

Next, as illustrated in FIG. 3A, a photoresist film 24 is formed on the entire surface by spin coating.

Next, by photolithography, openings 26 are formed in the photoresist film 24 down to the seed layer 22. The openings 26 are for forming interconnections 28 (see FIG. 3B).

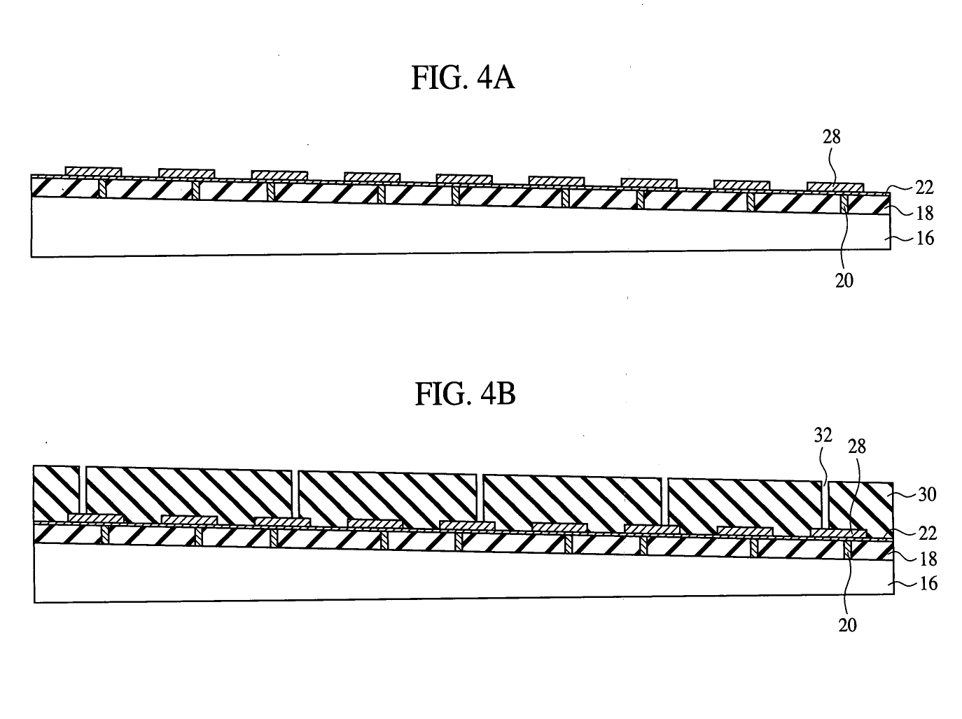

Next, as illustrated in FIG. 3B, interconnections 28 of Cu are formed in the openings 26 by electroplating. Then, the photoresist film 24 is released (see FIG. 4A).

Then, as illustrated in FIG. 4B, a photoresist film 30 is formed on the entire surface by spin coating.

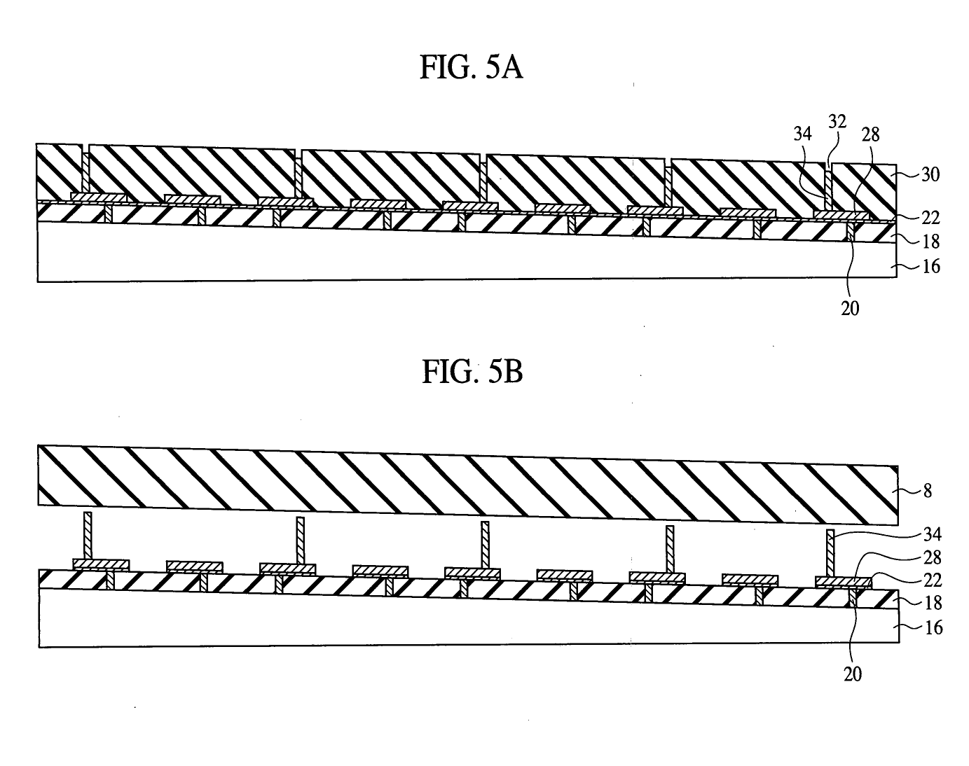

Next, openings 32 are formed in the photoresist film 30 down to the interconnections 28 by photolithography. The openings 32 are for forming conductor plugs 34 (see FIG. 5A).

Next, as illustrated in FIG. 5A, conductor plugs 34 of Cu are formed in the openings 32 by electroplating. Then, the photoresist film 30 is released.

Next, as illustrated in FIG. 5B, the exposed parts of the seed layer 22 are removed. When the seed layer 22 is removed, the exposed parts of surfaces of the interconnections 28 and the conductor plugs 34 are a little etched, but the interconnections 28 and the conductor plugs 34 are never excessively etched because the thickness of the seed layer 22 is sufficiently smaller in comparison with the sizes of the interconnections 28 and the conductor plugs 34.

Next, a resin film 8 is placed on the semiconductor substrate 16. The resin film 8 is the film for forming insulation layers (trade name: Ajinomoto Build-up Film: ABF) by AJINOMOTO CO., INC. The Ajinomoto Build-up Film is a resin film comprising a matrix of epoxy resin mixed with an inorganic filler of silica. The thickness of the resin film 8 is 30 μm.

The resin film may be, other than the above-described film, a liquid crystal polymer film (trade name: Vecstar) by KURARAY CO., LTD., a polyethylene naphthalate film (trade name: Teonex (R) PEN Film) by Teijin DuPont Films Limited.

The thickness of the resin film 8 is 30 μm here but is not essentially 30 μm. However, when the resin film 8 which is thinner than the TTV of the semiconductor substrate 16 is used, a part of the resin film is not cut. The thickness of the resin film 8 must be larger than the TTV of the semiconductor substrate 16.

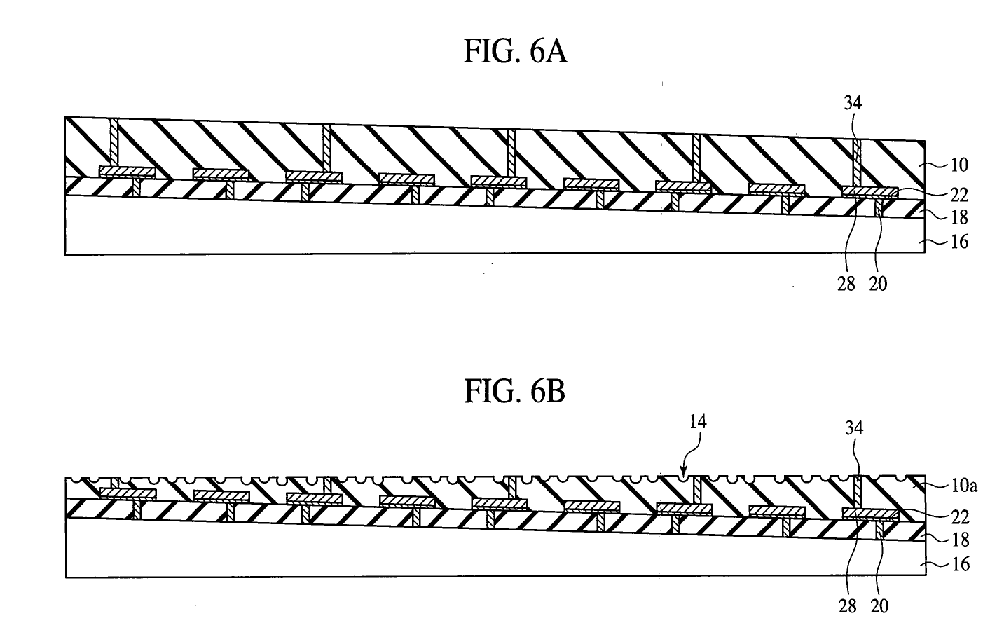

Next, by using a vacuum press, the resin film 8 is applied to the semiconductor substrate 16 with the inter-layer insulation film 18, etc. formed on (see FIG. 6A). Conditions for the vacuum press are, e.g., 100° C. and 1 MPa. Thus, the resin layer 10 of the resin film is formed on the base substrate.

Next, by thermal processing, the resin film 8 is solidified. Conditions for the thermal processing are, e.g., 170° C. and 1 hour.

Then, the semiconductor substrate 16 is fixed to a chuck table (not illustrated) by vacuum adsorption. The chuck table is a table for fixing wafers, etc. when they are processed. The semiconductor substrate 16 is fixed to the chuck table on the second surface (back surface) of the semiconductor substrate 16, i.e., the surface of the semiconductor substrate 16, where the resin layer 10 is not formed. It is preferable to use pin chuck when the semiconductor substrate 16 is fixed to the chuck table.

Next, while the semiconductor substrate 16 is being rotated, the surface part of the resin layer 10 and the upper parts of the conductor plugs 34 are cut with a cutting tool 12 of diamond to an about 10 μm-thickness of the resin layer 10 (see FIG. 1B).

Conditions for cutting the surface part, etc. of the resin layer 10, etc. are as exemplified below.

The rake of the cutting tool 12 is 0 degrees. The rake is an angle formed by a plane perpendicular to the cutting surface of an object-to-be-cut, and a front surface (the rake face) of the cutting tool blade, that is forward in the direction of advance of the cutting tool. Generally, as the rake angle is larger, the cut is better. However, the blade is more damaged, and the life of the blade tends to become shorter. The rake angle is suitably 0-30 degrees. The rake angle is set as described above in the present embodiment, in which the object-to-be-cut is the relatively soft resinous material.

The rotation number of the chuck table is, e.g., 1000 rpm. With such rotation number, the cut speed is about 5 m/second when the rotation radius is about 5 cm. The cut amount of the cutting tool 12 is, e.g., about 5 μm. As described above, the cut amount is a cut depth of the cutting tool at the time of a cut. The feed speed of the cutting tool 12 is, e.g., 50 μm/second. The feed speed is a speed at which the cutting tool is advanced radially of the chuck table in cutting, i.e., in the direction interconnecting one point on the outer peripheral edge of the chuck table and the rotation center.

When the surface of the resin layer 10 is cut under such conditions, ten-point height of irregularities Rz of the surface of the resin layer 10a after cut (hereinafter the resin layer after cut will be called the resin layer 10a to be discriminated from the resin layer 10 before cut) is, e.g., about 1-2 μm. The ten-point height of irregularities Rz of the surface of the conductor plugs is, e.g., about 5-15 nm.

The ten-point height of irregularities Rz is given by extracting a roughness curve by a reference length in the direction of its average line, summing an average value of the absolute values of altitudes of the highest peak to the fifth peak and an average value of the absolute values of altitudes of the lowest valley to the fifth valley measured in the direction of the depth ratio from the average line of the extracted part, and expressing the sum in micrometer (μm) (refer to JIS B 0601-1994). That is, the ten-point height of irregularities Rz is the difference between the average of the five highest peaks from to the mean line and the average depth to the five deepest valleys from the mean line.

FIG. 7 is views of the surfaces of the resin layer and the conductor plugs when the resin layer and the conductor plugs are cut with the cutting tool. FIG. 7A is a view showing a photomicrograph, and FIG. 7B is a schematic view of FIG. 7A.

As seen in FIG. 7, suitable concavities and convexities are formed substantially equally in the surface of the resin layer 10a. On the other hand, the upper portions of the conductor plugs 34 are specular.

After the surface part of the resin layer 10 has been cut, the TTV of the thickness from the second surface (back surface) of the semiconductor substrate 16 to the surface of the resin layer 10a is 1 μm or below. The value of the TTV is smaller, the better. However, when the TTV is 1 μm or below, there is no problem.

The ten-point height of irregularities Rz of the surface of the resin layer 10a is about 1-2 μm here but is not essentially about 1-2 μm.

When the ten-point height of irregularities Rz of the surface of the resin layer 10a is 0.5 μm or above, the adhesion between the resin layer 10a and the plating film can be sufficiently ensured. When the ten-point height of irregularities Rz of the surface of the resin layer 10a is below 0.5 μm, the depth of the concavities in the surface of the resin layer 10a is too small to cause the seed layer 36 and the plating film 44 to sufficiently anchor the resin layer 10. The anchor effect is insufficient. Accordingly, it is preferable that the ten-point height of irregularities Rz of the surface of the resin layer 10a is 0.5 μm or above.

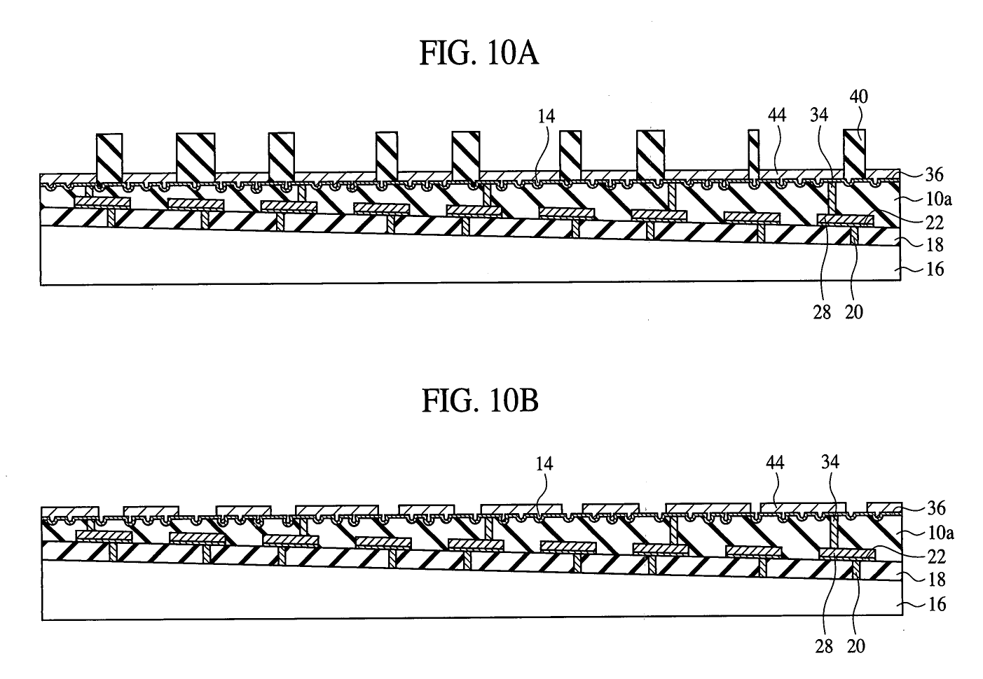

When the ten-point height of irregularities Rz of the surface of the resin layer 10a is 5 μm or below, the photoresist film formed on the resin layer 10a can be patterned, micronized, and interconnections of the plating film can be formed at an extremely small pitch. For the high integration of the semiconductor device, it is preferable that the thickness of the resin layer 10a is made as thin as about 10 μm. When the ten-point height of irregularities Rz of the surface of the resin layer 10a is above 5 μm, there is a risk that the lower interconnections 22 buried in the resin layer 10a and the upper interconnections 44 (see FIG. 10A) formed on the resin layer 10a may short with each other. It is not always easy to cut the surface of the resin layer so that the ten-point height of irregularities Rz of the surface of the resin layer 10a is 5 μm or above. Accordingly, it is preferable to set the ten-point height of irregularities Rz of the surface of the resin layer 10a at 5 μm or below.

For such reason, it is preferable to cut the surface of the resin layer 10 so that the ten-point height of irregularities Rz of the surface of the resin layer 10a is 0.5-5 μm. Conditions for cutting the surface of the resin layer 10 are suitably set, whereby the surface of the resin layer 10a can be set at a required roughness.

In a case that as the material of the resin layer 10, a resin film containing a filler mixed in the matrix of a resin is used, when the surface of the resin layer 10 is cut, the filler (not illustrated) is dug out of the resin layer 10, and pores are often formed in parts where the filler was dug out. However, the diameter of the filler is 2-5 μm, which is relatively small, and no excessively deep pores are formed in the surface of the resin layer 10a. No problem is caused.

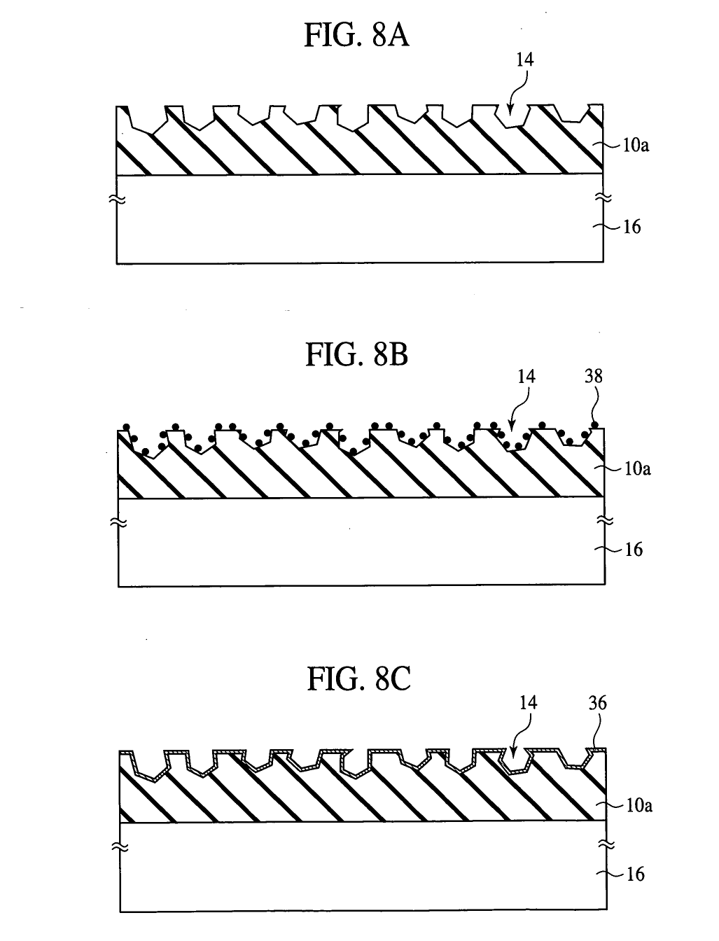

Thus, the concavities and convexities 14 of suitable roughness are formed in the surface of the resin layer 10a (see FIG. 8A).

The resin film 8 formed of the matrix of epoxy resin with an inorganic filler mixed in is used here. However, the filler is not essentially an inorganic material and can be an organic material. For example, a resin film formed of a matrix of epoxy resin containing a rubber-based organic filler may be used.

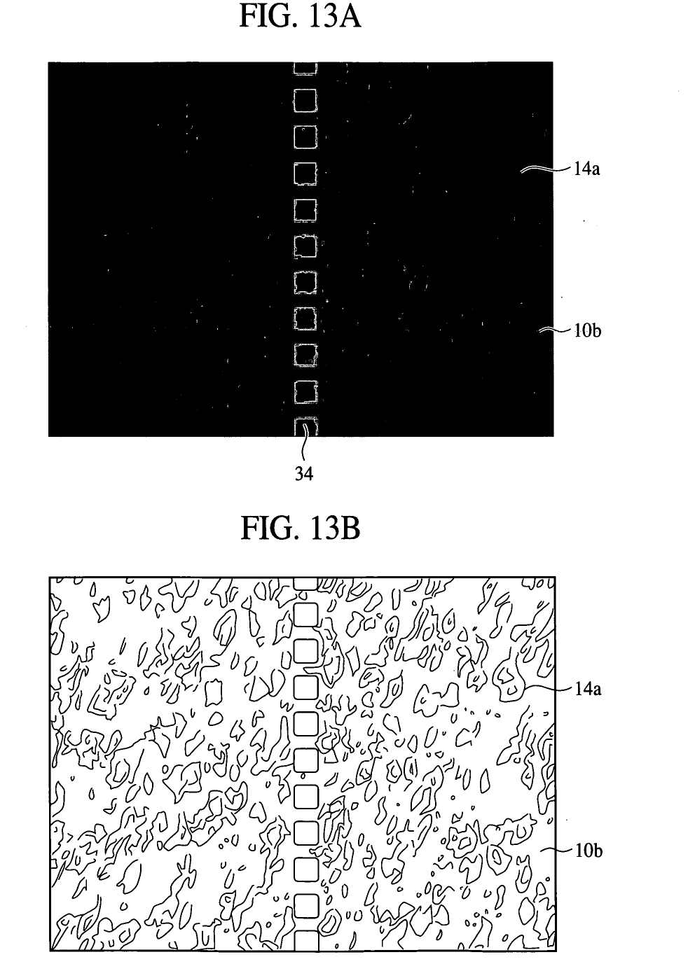

FIGS. 13A and 13B are views of a resin film formed of a matrix of epoxy resin containing a rubber-based filler, which is cut with a cutting tool. FIG. 13A is a view showing a photomicrograph, and FIG. 13B is a schematic view of FIG. 13A.

As seen in FIG. 13, when the filler is a rubber-based material, suitable concavities and convexities 14a are formed in the surface of the resin layer 10b. On the other hand, the upper surface of conductor plugs 34 are specular.

Thus, the filler mixed in the resinous matrix may be an organic material.

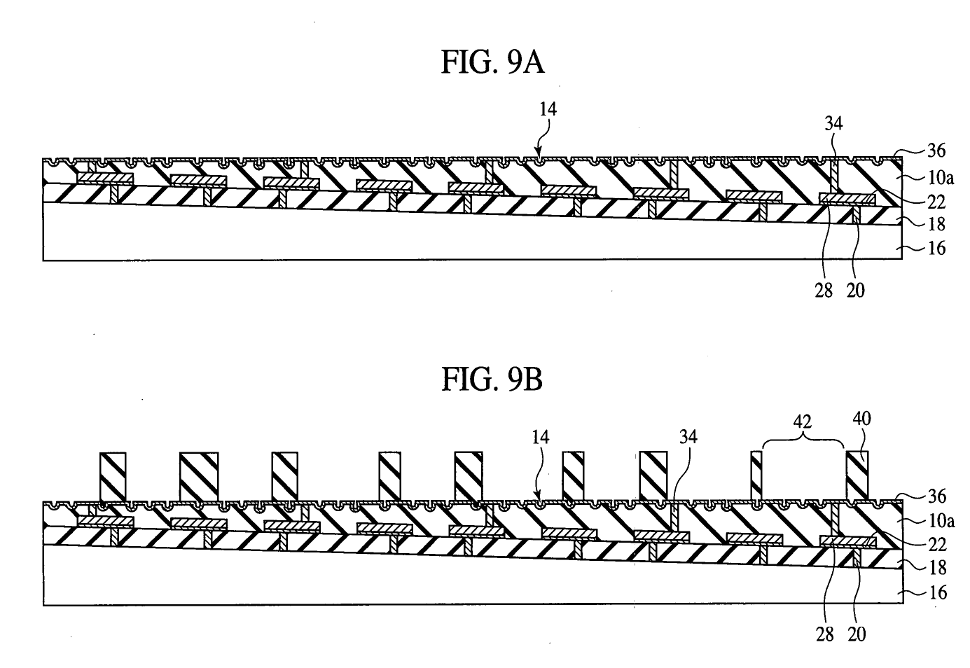

Next, a seed layer 36 of copper or nickel is formed on the resin layer 10 by electroless plating (see FIG. 8C or FIG. 9A). The seed layer 36 is formed as exemplified below.

First, the resin layer 10a is conditioned by using a conditioner. The conditioning is chemical liquid processing for removing contaminants from the surface of the resin layer 10a and making the surface of the resin layer 10a easy for a catalyst to adhere to. The conditioner is, e.g., a conditioner (Model: 3320) by Tekran Inc. The conditioning temperature is, e.g., 50° C. The conditioning period of time is, e.g., 5 minutes. Then, the surface of the resin layer 10a is rinsed with water.

Then, as illustrated in FIG. 8B, a catalyst 38 which is to be the core in forming the electroless plating film is adhered to the surface of the resin layer 10a.

Specifically, after the resin layer 10a is immersed in a chemical liquid for the pre-processing, the resin layer 10a is immersed in the catalyst liquid without rinsing off the chemical liquid for the pre-processing. The chemical liquid for the preprocessing is, e.g., a chemical liquid for the pre-processing (type: Cataprep 404) by Rohm and Haas Electronic Materials. The temperature of the chemical liquid for the pre-processing for the resin layer 10a to be immersed in is, e.g., the room temperature. The time of immersing the resin layer 10a in the chemical liquid for the pre-processing is 90 seconds. The catalyst liquid is a solution containing Pd—Sn complex. For example, a catalyst liquid (type: Cataposit 404) by Rohm and Haas Electronic Materials is used. The temperature of the catalyst liquid at the time of immersing the resin layer 10a is, e.g., 55° C. The period time of immersing the resin layer 10a in the catalyst liquid is, e.g., 3 minutes. Thus, the Pd—Sn complex adheres to the surface of the resin layer 10a. Then, the surface of the resin layer 10a is rinsed with water. Next, accelerator processing is performed. To be specific, the resin layer 10a is immersed in an accelerator. Thus, tin salt is dissolved, and the catalyst 38 of metal palladium is produced by the oxidation-reduction reaction. The accelerator is an accelerator (Type: Acceleator 19E) by Rohm and Haas Electronic Materials.

Thus, the catalyst 38 which is to be core in forming the electroless plating film is adhered to the surface of the resin layer 10a.

Then, the resin layer 10a is immersed in an electroless plating liquid. The electroless plating liquid is, e.g., an electroless plating liquid (Type: Cuposit 328) by Rohm and Haas Electronic Materials. Thus, the copper ions are reduced with the electrons emitted when the reducing agent in the electroless plating liquid is oxidized on the surface of the palladium 38, and the electroless plating film 36 of copper is formed.

Thus, the seed layer 36 of the electroless plating film of, e.g., a 0.3-0.5 μm-thickness is formed.

Because of the relatively thin seed layer 38 formed on the resin layer 10a having the concavities formed in the surface, the parts of the seed layer 38 formed in the concavities 14 are surely secured in the concavities 14. Accordingly, the adhesion between the seed layer 36 and the resin layer 10a can be sufficiently ensured.

Next, as illustrated in FIG. 9B, a photoresist film 40 is formed on the entire surface by spin coating.

Then, openings 42 are formed in the photoresist film 40 down to the seed layer 36 by photolithography. The openings 42 are for forming interconnections 44 (see FIG. 8A). Without excessively deep pores formed in the surface of the resin layer 10a, no excessively deep concavities are formed in the surface of the seed layer 36 either. Accordingly, even when the photoresist film is patterned, micronized, the pattern of the photoresist film can be good.

Then, as illustrated in FIG. 10A, the interconnections 44 of Cu are formed on the seed layer 36 in the openings 42. As described above, even when the photoresist film is patterned, micronized, the pattern can be good, which permits the interconnections 44 to be formed at an extremely small pitch. The adhesion between the seed layer 36 and the resin layer 10a is sufficiently secured, whereby the interconnections 44 can be surely secured to the resin layer 10a via the seed layer 36.

Then, as illustrated in FIG. 10B, the photoresist film 40 is released.

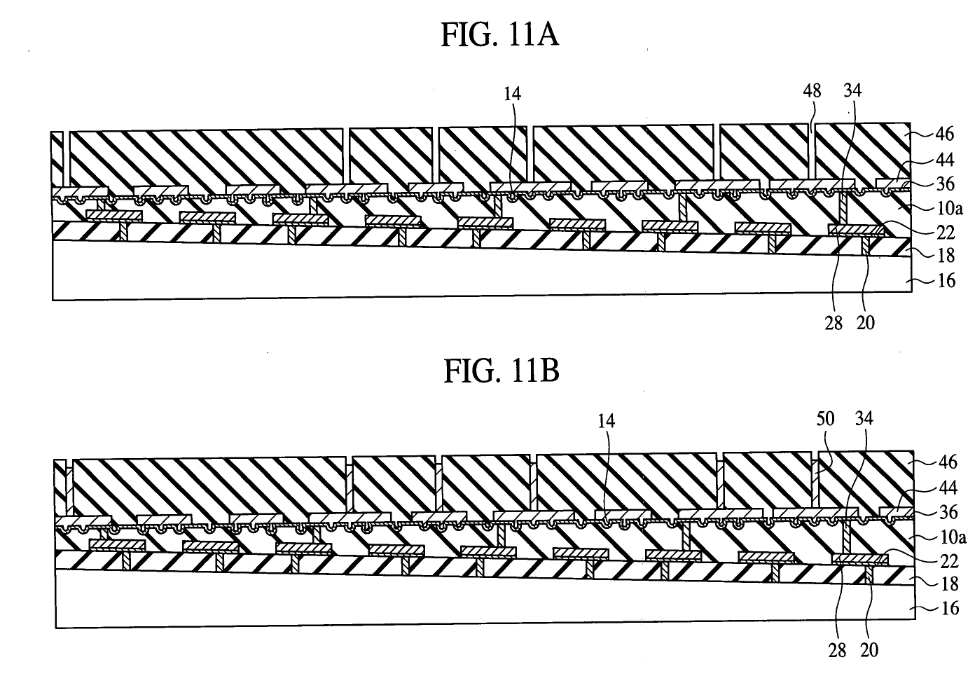

Next, as illustrated in FIG. 11A, a photoresist film 46 is formed by spin coating on the entire surface of the resin layer 10a with the interconnections 44 formed on.

Next, openings 48 are formed down to the interconnections 44 by photolithography. The openings 48 are for forming conductor plugs 50 (see FIG. 11B).

As illustrated in FIG. 11B, the conductor plugs 50 of Cu are formed in the openings 48 by electroplating. Then, the photoresist film 46 is released.

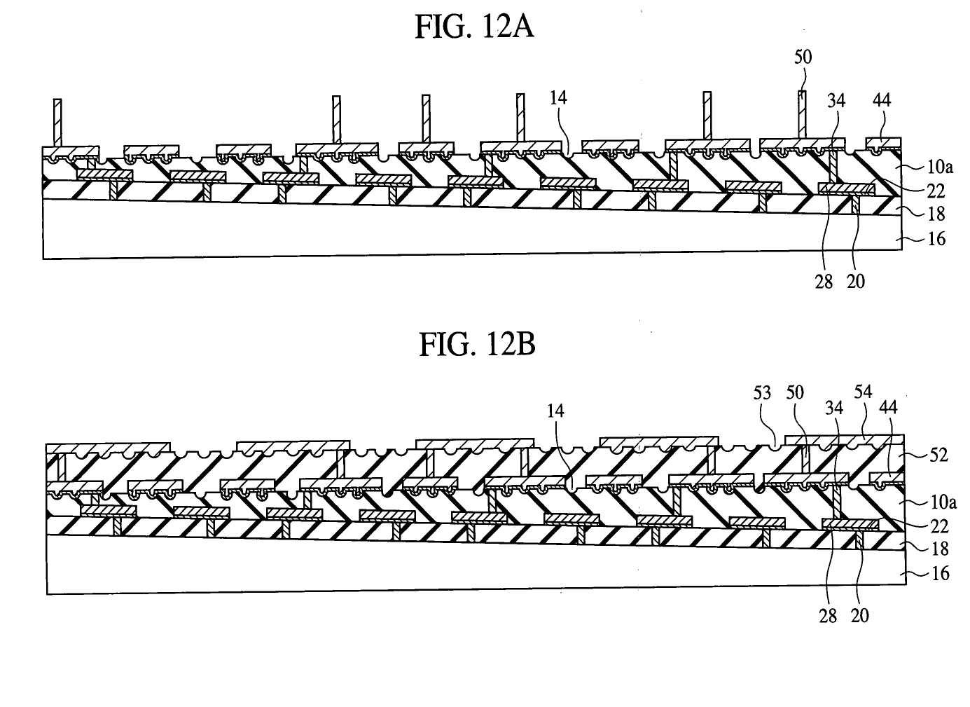

Then, as illustrated in FIG. 12A, the seed layer 36 is etched off. When the seed layer 36 is etched off, the surfaces of the interconnections 44 and the conductor plugs 48 are also a little etched. However, because of the sufficiently smaller thickness of the seed layer 36 than the sizes of the interconnections 44 and the conductor plugs 48, the interconnections 44 and the conductor plugs 48 are never excessively etched.

Then, as illustrated in FIG. 12B, a resin film 52 is prepared. The resin film 52 is the same resin film (film for forming insulation layers by AJINOMOTO CO., INC.) (trade name: Ajinomoto Build-up Film: ABF) as the resin film 8 described above is used.

Then, the resin film 52 is applied to the resin layer 10a by a vacuum press apparatus. Conditions for the vacuum pressing are, e.g., 100° C. and 1 MPa, as are those for vacuum pressing the resin film 8. Thus, the resin layer 52 of the resin film is formed on the resin layer 10a with the interconnections 44, the conductor plugs 50, etc. formed on.

Then, the resin layer 52 is solidified by thermal processing. Conditions for the thermal processing are, e.g., 170° C. and 1 hour, as are those for solidifying the resin film 8 described above.

Then, the surface part of the resin layer 52 is cut. Conditions for cutting the surface part of the resin layer 52 are the same as those for cutting the surface part of the resin layer 10. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When the cut is performed under these conditions, the suitable concavities and convexities 53 are formed in the surface of the resin layer 52. Thus, the ten-point height of irregularities Rz of the surface of the resin layer 52 is, e.g., about 1-2 μm.

The ten-point height of irregularities Rz of the surface of the resin layer 52 is about 1-2 μm here but is not essentially about 1-2 μm. The surface of the resin layer 52 may be cut so that the ten-point height of irregularities Rz of the surface of the resin layer 52 is, e.g., 0.5-5 μm.

Then, a seed layer (not illustrated) is formed on the resin layer 52 and the conductor plugs 50 by electroless plating. The technique for forming the seed layer is the same as the technique for forming the seed layer 36 described above. That is, after the conditioning, the adhesion of the catalyst to the surface of the resin layer, etc., the seed layer is formed by electroless plating.

Next, a photoresist film (not illustrated) is formed on the entire surface by spin coating.

Then, openings (not illustrated) are formed down to the seed layer by photolithography.

Next, interconnections 54 of Cu are formed in the openings by electroplating. Then, the photoresist film is released.

Then, a resin layer and a metal interconnection layer may be further formed thereon.

Thus, the semiconductor device fabrication method according to the present embodiment is performed by using the plating method according to the present embodiment.

The plating method and the semiconductor device fabrication method according to the present embodiment is characterized mainly in that the surface of the resin layer is cut with the cutting tool so that the ten-point height of irregularities of the surfaces of the resin layers is 0.5-5 μm.

In the conventional plating method, as described above, the surface of the resin layer is roughened by the desmearing treatment. When the surface of the resin layer is roughened by the desmearing treatment, often about ten-odd μm-pores are formed. It is difficult to form a micronized pattern of a photoresist film on a resin layer with ten-odd μm-pores formed in. Accordingly, it is very difficult to form interconnections of a plating film on the resin layer at an extremely small pitch without causing short circuits, etc.

However, in the present embodiment, the surface of the resin layer is cut with the cutting tool, whereby the surface of the resin layer can be set at suitable roughness. According to the present embodiment, the surface of the resin layer can be suitably roughened, whereby the adhesion between the seed layer and the resin layer can be sufficiently ensured. Furthermore, extremely deep pores as formed by the desmearing treatment are not formed in the surface of the resin layer, which allows a micronized pattern of a photoresist film to be formed on the resin layer. Thus, according to the present embodiment, interconnections, etc. of a plating film can be formed on a resin film at an extremely small pitch while high reliability being ensured.

### A SECOND EMBODIMENT

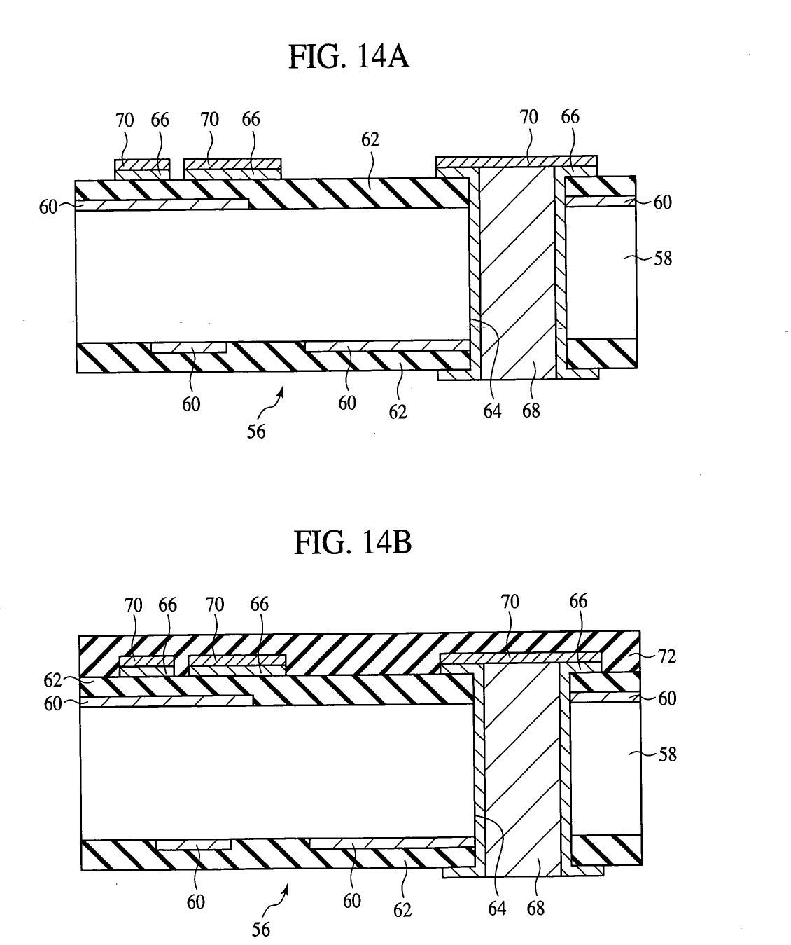

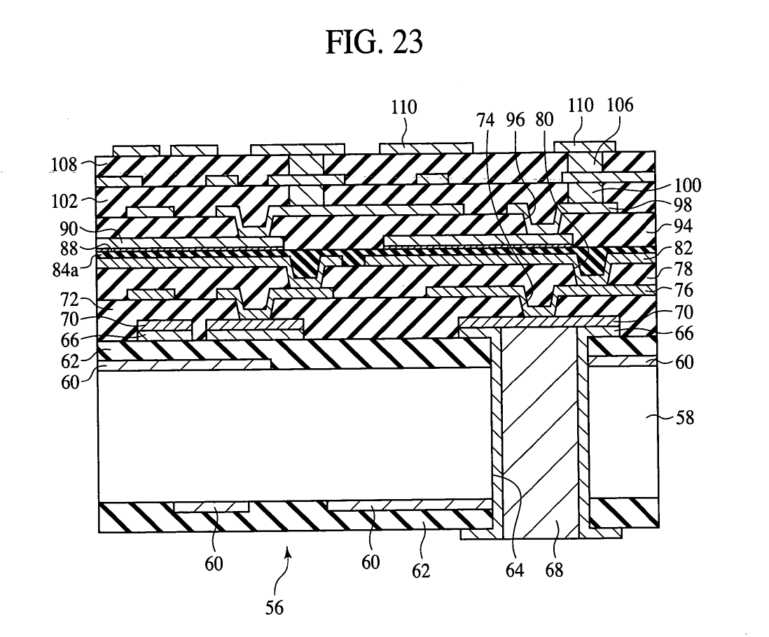

The circuit board fabrication method according to a second embodiment of the present invention will be explained with reference to FIGS. 14A to 23. FIGS. 14A to 23 are sectional view of a circuit board in the steps of the circuit board fabrication method, which illustrate the method. The same members of the present embodiment as those of the plating method and the semiconductor device fabrication method according to the first embodiment illustrated in FIGS. 1A to 12B are represented by the same reference numbers not to repeat or to simplify their explanation.

The circuit board fabrication method according to the present embodiment is characterized mainly in that the dielectric film of capacitors is formed of a resin sheet, and the surface part of the dielectric film of the resin sheet is cut with a cutting tool.

First, as illustrated in FIG. 14A, a core layer 56 is prepared. The core layer 56 has the following constitution, for example. That is, interconnections 60, etc. are formed on the upper surface and the under surface of a base substrate 58 of, e.g., epoxy resin. Insulation films 62 of, e.g., epoxy resin are formed respectively on the upper side and the under side of the base substrate 58 with the interconnections 60, etc. are formed on. A through-hole 64 is formed in the base substrate 58 and the insulation films 62. A conductor film 66 is formed in the through-hole 64. The conductor film 66 is formed also on the insulation layer 62. A via 68 is buried in the through-hole 64 with the conductor film 66 formed on. A conductor film 70 is formed on the via 68 and the conductor film 66. The conductor film 66 and the conductor film 70 form interconnections.

Next, a resin film 72 of epoxy resin is placed on the core layer 56. The resin film 72 is ABF (Ajinomoto Build-up Film), which is a film for forming insulation films, by AJINOMOTO CO., INC. The thickness of the resin film 72 is 60 μm.

Then, the resin film 72 is applied to the core layer 56 with a vacuum press apparatus. Conditions for vacuum pressing the resin film 72 are, e.g., 100° C. and 1 MPa, which are the same as conditions for vacuum pressing the resin film 8 described in the first embodiment. Thus, an insulation film 72 of the resin film is formed on the base substrate 58 (see FIG. 14B).

Then, the resin layer 72 is solidified by thermal processing. Conditions for the thermal processing are, e.g., 170° C. and 1 hour, which are the same as those for solidifying the resin layer 10 in the first embodiment.

Then, the surface of the resin layer 72 is cut with a cutting tool. Conditions for cutting the surface part of the resin layer 72 are the same as conditions for cutting the surface of the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When the cut is performed under these conditions, the ten-point height of irregularities Rz of the surface of the resin layer 72 is, e.g., about 1-2 μm.

The ten-point height of irregularities Rz of the surface of the resin layer 72 is about 1-2 μm here but is not essentially about 1-2 μm. The surface of the resin layer 72 may be cut so that the ten-point height of irregularities Rz of the surface of the resin layer 72 is, e.g., 0.5-5 μm.

Then, contact holes 74 are formed in the resin layer 72 down to the interconnections 70 by photolithography.

Then, a seed layer (not illustrated) of copper or nickel is formed on the entire surface by electroless plating. The technique for forming the seed layer is the same as the technique for forming the seed layer 36 described in, e.g., the first embodiment. That is, after the conditioning, the adhesion of a catalyst to the surface of the resin layer, etc. are performed, the seed layer is formed by electroless plating.

Then, a photoresist film (not illustrated) is formed on the entire surface by spin coating.

Next, openings (not illustrated) are formed down to the seed layer by photolithography. The openings are for forming interconnections 76.

Next, the interconnections 76 of Cu are formed in the openings by electroplating. Then, the photoresist film is released.

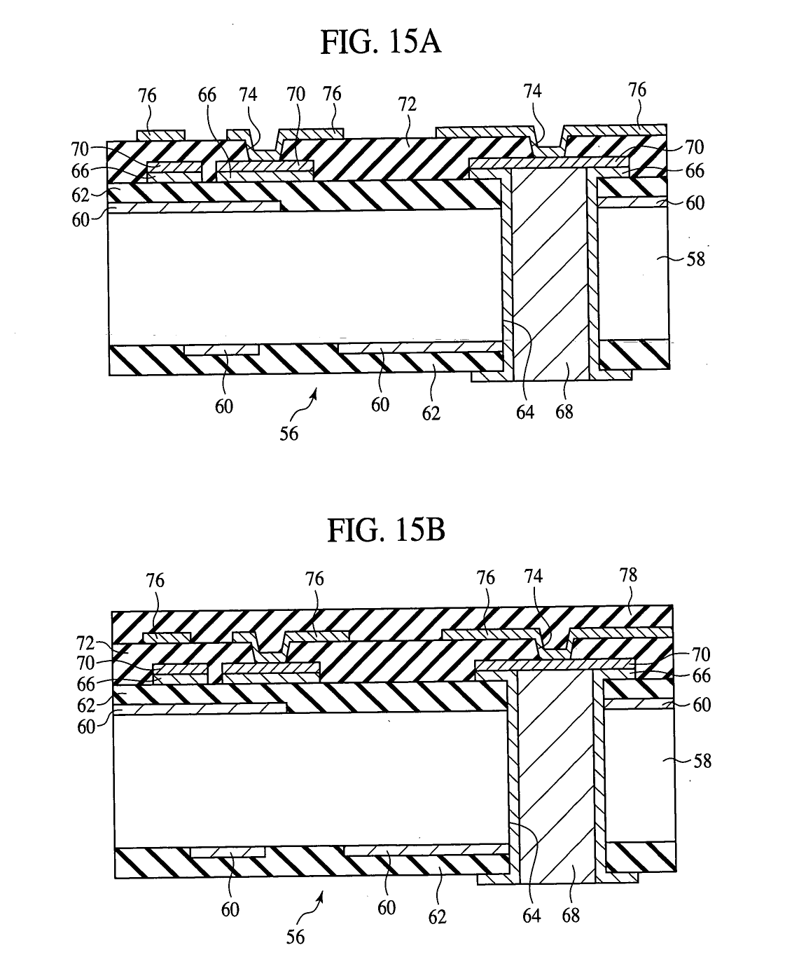

Next, the exposed parts of the seed layer are etched off (see FIG. 15A).

Then, a resin film 78 is adhered to the base substrate 58 with a vacuum press apparatus . The resin film 78 is ABF (Ajinomoto Build-up Film), which is a film for forming insulation layer by AJINOMOTO CO., INC. The thickness of the resin film 78 is 60 μm. Conditions for the vacuum pressing are, e.g., 100° C. and 1 MPa, which are the same as those for vacuum pressing the resin film 8 described in the first embodiment. Thus, an insulation film 78 of the resin film is formed on the base substrate 58 (see FIG. 15B).

Next, the resin layer 78 is solidified by thermal processing. Conditions for the thermal processing are, e.g., 170° C. and 1 hour, which are the same as those for solidifying the resin layer 10 described in the first embodiment.

Then, the surface of the resin layer 78 is cut with the cutting tool. Conditions for cutting the surface of the resin layer 78 are the same as those for cutting the surface part of the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When the cut is performed under these conditions, the ten-point height of irregularities Rz of the surface of the resin layer 78 is, e.g., about 1-2 μm.

The ten-point height of irregularities Rz of the surface of the resin layer 78 is about 1-2 μm here but is not essentially about 1-2 μm. The surface of the resin layer 78 may be cut so that the ten-point height of irregularities Rz of the surface of the resin layer 78 is, e.g., 0.5-5 μm.

Then, contact holes 80 are formed in the resin layer 78 down to the interconnections 76 by photolithography.

Next, a seed layer (not illustrated) of copper or nickel is formed on the entire surface by electroless plating. The technique for forming the seed layer is the same as that for forming the seed layer 36 described in, e.g., the first embodiment. That is, after the conditioning, the adhesion of a catalyst to the surface of the resin layer, etc. are performed, the seed layer is formed by electroless plating.

Then, a photoresist film (not illustrated) is formed on the entire surface by spin coating.

Next, openings are formed down to the seed layer are formed by photolithography. The openings are for forming the lower electrodes 82 of capacitors.

Next, the lower electrodes 82 of Cu are formed in the openings by electroplating. Then, the photoresist film is released.

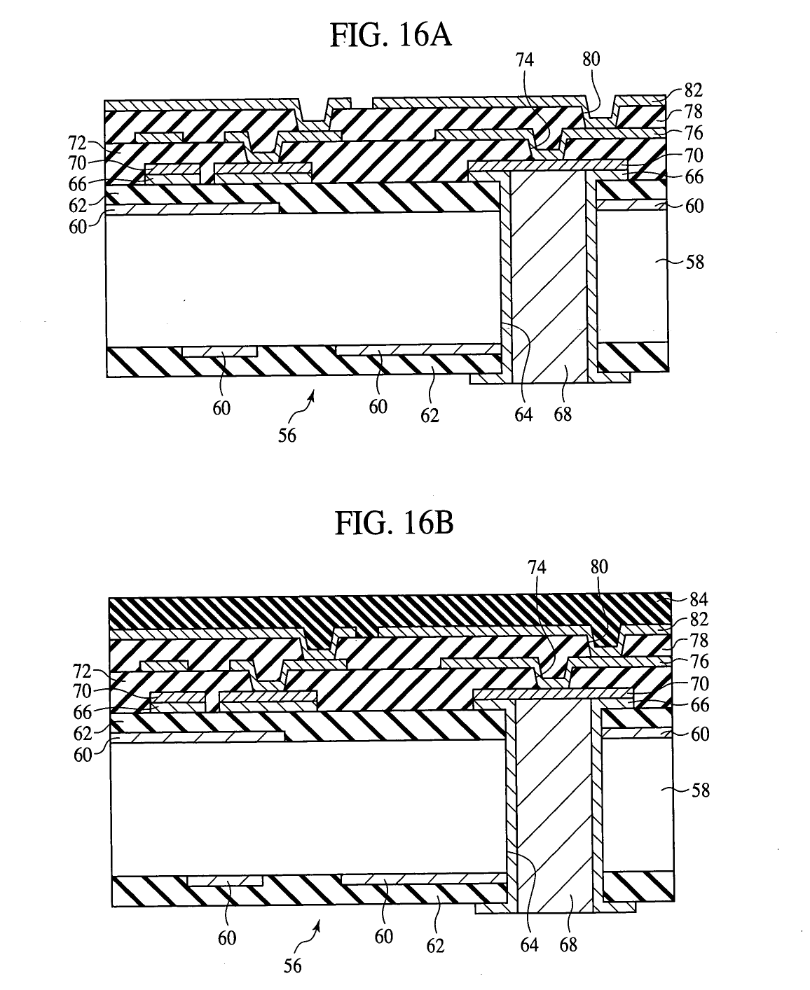

Next, the exposed parts of the seed layer are etched off (see FIG. 16A).

Then, a resin film 84 is prepared. The resin film 84 is a resin film formed of a matrix of epoxy resin mixed with a filler of a high-dielectric constant substance whose specific dielectric constant is higher than the resin. The filler of a high-dielectric constant substance is formed of, e.g., BaTiO₃. The specific dielectric constant of the resin used as the matrix is about 3-5. The thickness of the resin film 84 is 60 μm.

The filler of a high-dielectric constant substance is BaTiO₃ here but is not essentially BaTiO₃. A material whose specific dielectric constant is higher than that of the resin forming the matrix can be used as the material of the filler. For example, the filler can be high-dielectric constant substance, such as CaTiO₃, SrTiO₃, ZnTiO₃, PbTiO₃, CaZrO₃, BaZrO₃, PbZrO₃, Ba_{X}Sr_{1-X}TiO₃, BaTi_{X}Zr_{1-X}O₃, PbZr_{X}Ti_{1-X}O₃, Pb_{X}La_{1-X}Zr_{Y}Ti_{1-Y}O₃, La₂Ti₂O₇, Nd₂Ti₂O₇ or others. The filler can be a mixture of them.

Then, as illustrated in FIG. 16B, the resin film 84 is applied to the base substrate 58 with a vacuum press apparatus. Conditions for the vacuum pressing are, e.g., 100° C. and 1 MPa, which are the same as those for the vacuum pressing the resin film 8 described in the first embodiment. Thus, a dielectric film 84 of the resin film is formed on the base substrate 58.

Next, thermal processing is performed to solidify the resin layer 84. Conditions for the thermal processing are, e.g., 170° C. and 1 hour, which are the same as those for solidifying the resin layer 10 described in the first embodiment. The thermal processing is for solidifying the resin layer 84 itself. Accordingly the thermal processing can be performed under the same conditions as those described above in solidifying the resin layer 10.

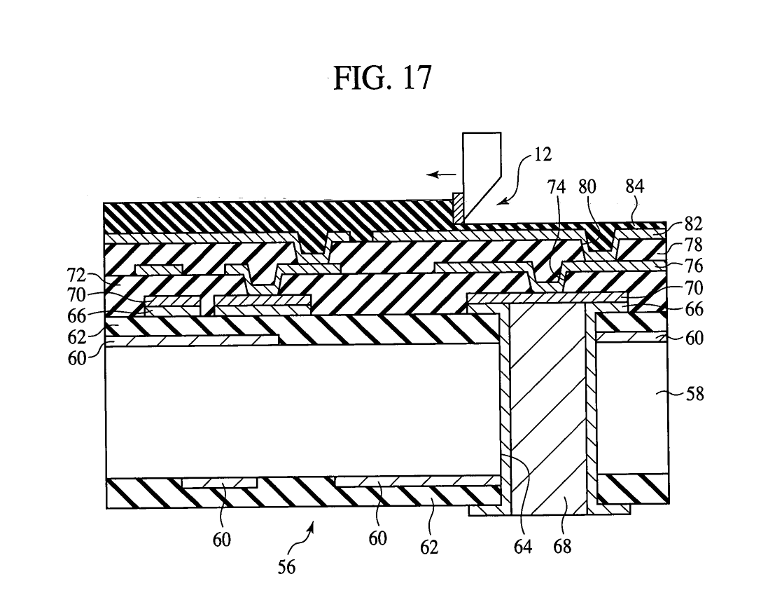

Then, as illustrated in FIG. 17, the surface of the resin layer 84 is cut with the cutting tool 12. Conditions for cutting the surface of the resin layer 84 are the same as those for cutting the surface part of, e.g., the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When the cut is performed under these conditions, the ten-point height of irregularities Rz of the surface of the resin layer 84a after the surface part is cut is, e.g., about 1-2 μm. Conditions for cutting the surface part of the resin layer 84 are suitably set, whereby the surface part of the resin layer 84a after cut can have required roughness. In cutting the surface part of the resin layer 84, the surface part of the resin layer 84 is cut until the thickness of the resin layer 84 present on the bottom electrodes 82 becomes, e.g., about 4 μm. Thus, as illustrated in FIG. 17, the dielectric film 84a of the resin layer of, e.g., a 4 μm-thickness is formed.

The ten-point height of irregularities Rz of the surface of the resin layer 84a is about 1-2 μm here but is not essentially about 1-2 μm. The surface of the resin layer 84a may be cut so that the ten-point height of irregularities Rz of the surface of the resin layer 84a is, e.g., 0.5-5 μm.

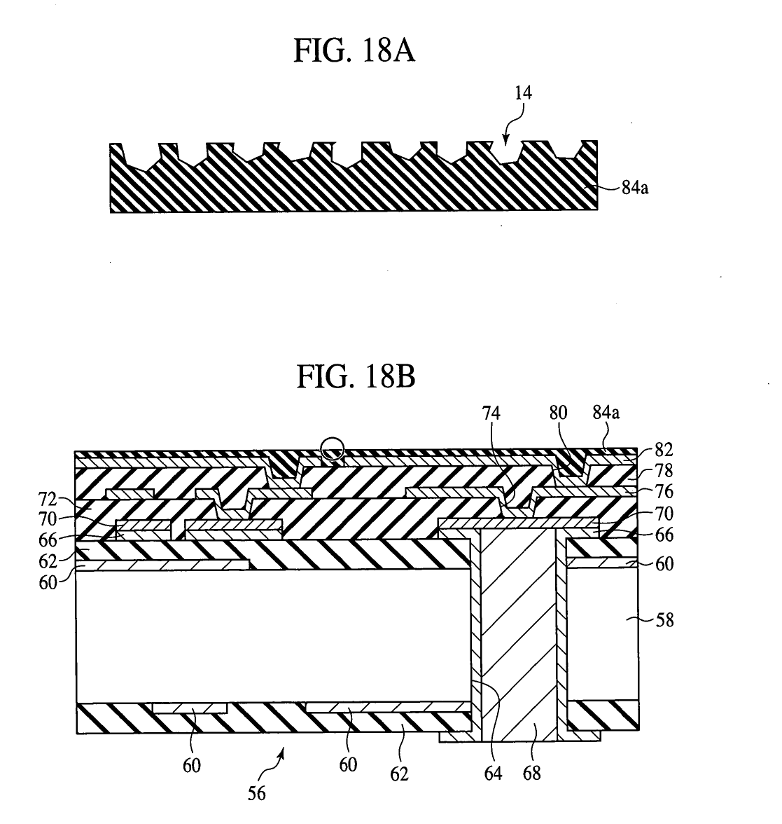

FIG. 18A is an enlarged view of the circled part of the drawing illustrated in FIG. 18B. As illustrated in FIG. 18A, concavities and convexities 14 are formed in the surface of the resin layer 84a.

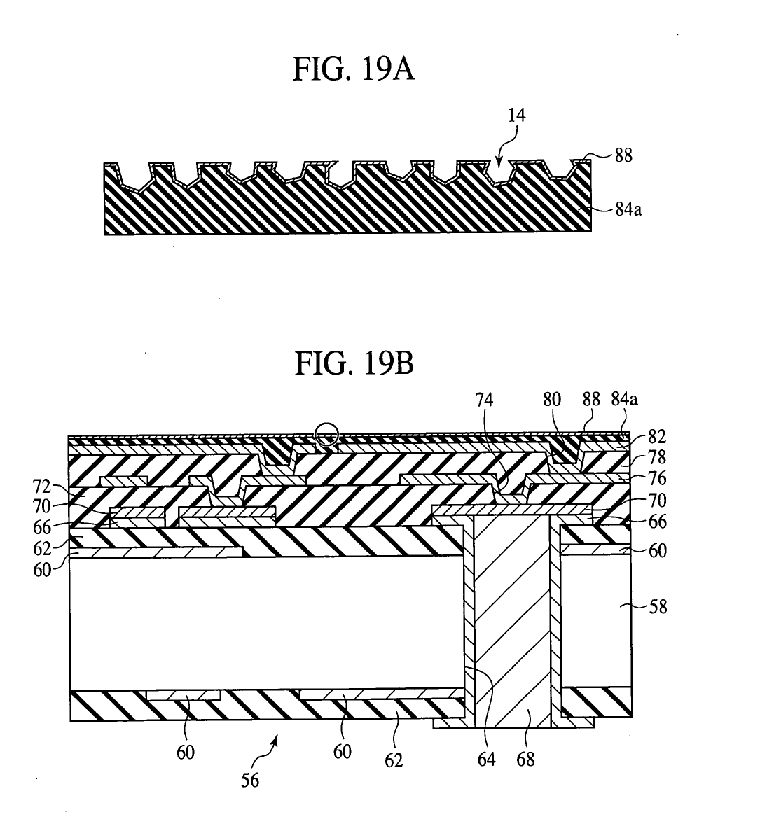

Then, as illustrated in FIGS. 19A and 19B, a seed layer 88 is formed of copper or nickel on the entire surface by electroless plating. The method for forming the seed layer 88 is the same as that for forming the seed layer 36 described in, e.g., the first embodiment. That is, after the conditioning, the adhesion of a catalyst to the surface of the resin layer, etc. are performed, the seed layer 88 is formed by electroless plating. FIG. 19A is an enlarged view of the circled part of the drawing illustrated in FIG. 19B.

Next, a photoresist film (not illustrated) is formed on the entire surface by spin coating.

Next, openings (not illustrated) are formed down to the seed layer by photolithography. The openings are for forming upper electrodes 90.

Next, the upper electrodes 90 of Cu are formed in the openings by electroplating. Then, the photoresist film is released.

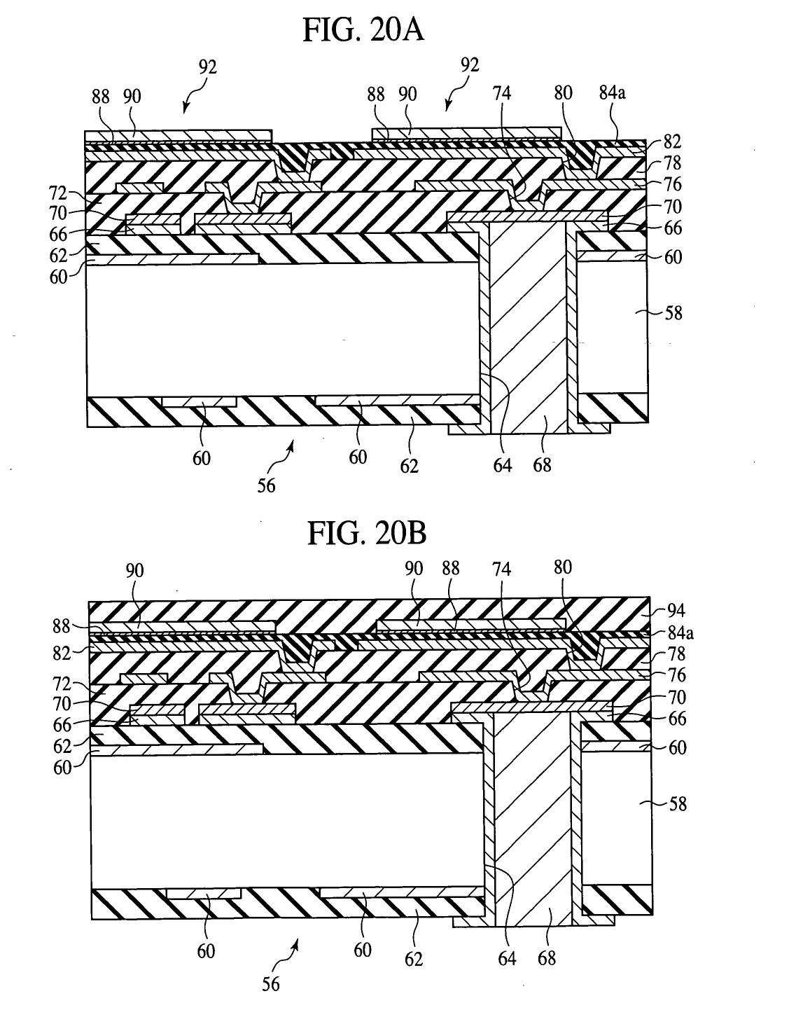

Next, the exposed parts of the seed layer 88 are etched off. Thus, capacitors 92 each including the lower electrode 82, the dielectric film 84a and the upper electrode 90 are formed (see FIG. 20A).

Next, as illustrated in FIG. 20B, the resin film 94 is applied to the substrate with a vacuum press appartus. The resin film 94 is ABF (Ajinomoto Build-up Film), which is a film for forming insulation films by AJINOMOTO CO., INC. The thickness of the resin film 94 is 60 μm. Conditions for the vacuum pressing are, e.g., 100° C. and 1 MPa, which are the same as those for vacuum pressing the resin film 8 described in the first embodiment. Thus, the resin layer 94 of the resin film is formed on the base substrate 58.

Next, the resin layer 94 is solidified by thermal processing. Conditions for the thermal processing are, e.g., 170° C. and 1 hour, which are the same as those for solidifying the resin layer 10 described in the first embodiment.

Then, the surface part of the resin layer 94 is cut with the cutting tool. Conditions for cutting the surface part of the resin layer 94 are the same as those for cutting the surface part of the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When the cut is performed under these conditions, the ten-point height of irregularities Rz of the surface of the resin layer 94 is, e.g., about 1-2 μm.

The ten-point height of irregularities Rz of the surface of the resin layer 94 is about 1-2 μm here but is not essentially about 1-2 μm. The surface of the resin layer 94 may be cut so that the ten-point height of irregularities Rz of the surface of the resin layer 94 is, e.g., 0.5-5 μm.

Then, contact holes 96 are formed in the resin layer 94 down to the upper electrodes 90 of the capacitors 92 by photolithography.

Then, a seed layer (not illustrated) of copper or nickel is formed on the entire surface by electroless plating. The technique for forming the seed layer is the same as that for forming the seed layer 36 described in, e.g., the first embodiment. That is, after the conditioning, the adhesion of a catalyst to the surface of the resin layer, etc. are formed, the seed layer is formed by electroless plating.

Next, a photoresist film (not illustrated) is formed on the entire surface by spin coating.

Next, opening (not illustrated) are formed down to the seed layer by photolithography. The openings are for forming interconnections 98.

Next, the interconnections 98 of Cu are formed in the openings by electroplating. Then, the photoresist film is released.

Next, a photoresist film (not illustrated) is formed on the entire surface by spin coating.

Next, openings (not illustrated) are formed down to the interconnections 98 by photolithography. The opening are for forming conductor plugs 100.

Then, conductor plugs 100 of Cu are formed in the openings by electroplating, and then the photoresist film is released.

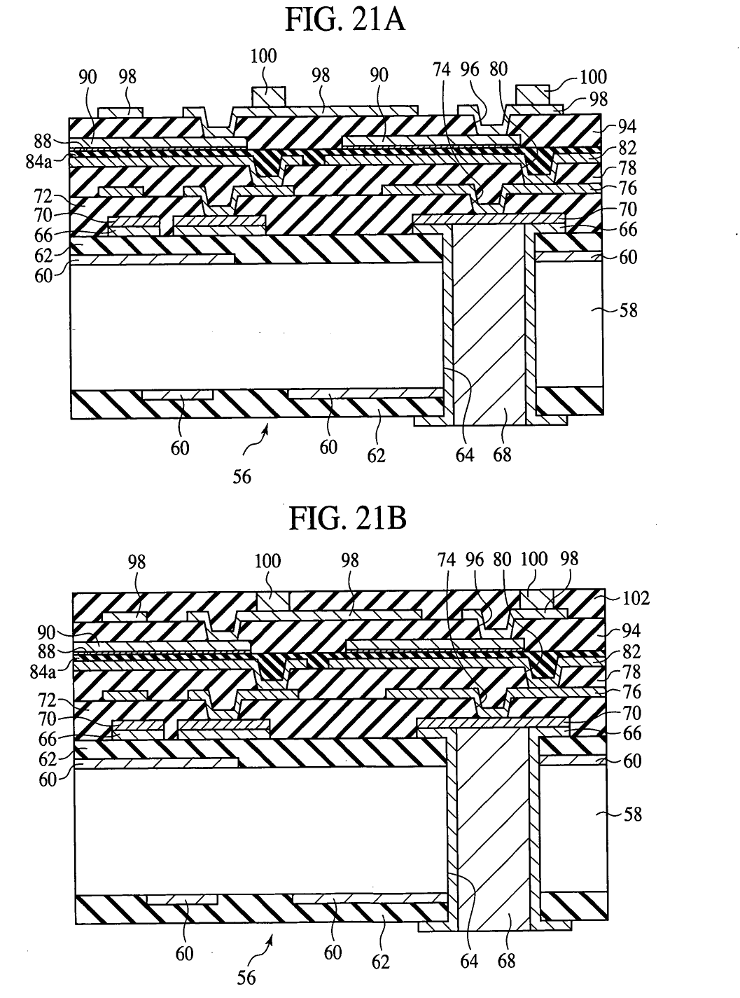

Next, the exposed parts of the seed layer are etched off (see FIG. 21A).

Next, the resin film 102 is applied to the base substrate 58 with a vacuum press apparatus. The resin film 102 is ABF (Ajinomoto Build-up Film), which is a film for forming insulation films by AJINOMOTO CO., INC. Conditions for the vacuum pressing are, e.g., 100° C. and 1 MPa, which are the same as those for vacuum pressing the resin film 8 described in the first embodiment. Thus, the resin film 102 of the resin film is formed on the resin layer 94 with the interconnections 98 and the conductor plugs 100 formed on.

Next, the resin layer 102 is solidified by thermal processing. Conditions for the thermal processing are the same as those for solidifying the resin layer 10 described in the first embodiment, i.e., 170° C. and 1 hour.

Then, the surface of the resin layer 102 and the surfaces of the conductor plugs 100 are cut with the cutting tool. Conditions for cutting the surface of the resin layer 102 and the surfaces of the conductor plugs 100 are the same as conditions for cutting the surface part of the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. The ten-point height of irregularities Rz of the surface of the resin layer 102 becomes, e.g., about 1-2 μm. The ten-point height of irregularities Rz of the surfaces of the conductor plugs 100 becomes, e.g., about 5-15 nm (see FIG. 21B).

The ten-point height of irregularities Rz of the surface of the resin layer 102 is about 1-2 μm here but is not essentially about 1-2 μm. The surface of the resin layer 102 may be cut so that the ten-point height of irregularities Rz of the surface of the resin layer 102 is, e.g., 0.5-5 μm.

Then, a seed layer (not illustrated) is formed of copper or nickel on the entire surface by electroless plating. The method for forming the seed layer is the same as that for forming the seed layer 36 in, e.g., the first embodiment. That is, after the conditioning, the adhesion of a catalyst to the surface of the resin layer, etc. are performed, the seed layer is formed by electroless plating.

Next, a photoresist film (not illustrated) is formed on the entire surface by spin coating.

Next, openings (not illustrated) are formed down to the seed layer by photolithography. The openings are for forming interconnections 104.

Then, the interconnections 104 of Cu are formed in the openings by electroplating. Then, the photoresist film is released.

Next, a photoresist film (not illustrated) is formed on the entire surface by spin coating.

Then, openings (not illustrated) are formed down to the interconnections 104 by photolithography. The openings are for forming conductor plugs 106.

Next, the conductor plugs 106 of Cu (copper) are formed in the openings by electroplating. Then, the photoresist film is released.

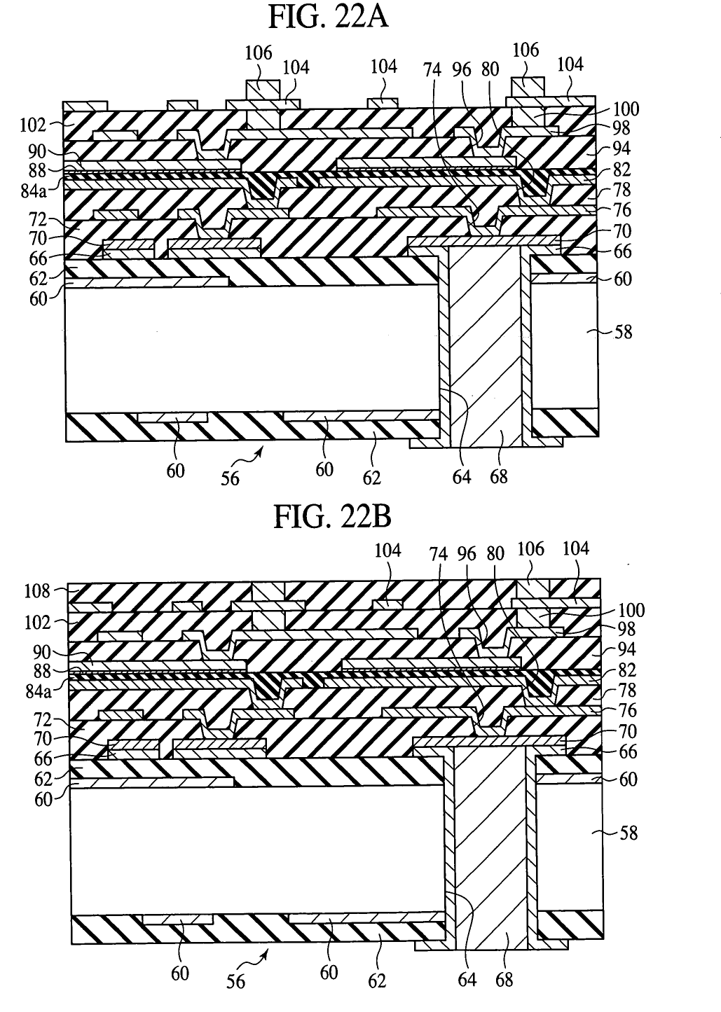

The exposed parts of the seed layer are etched off (see FIG. 22A).

Next, the resin film 108 is applied to the base substrate 58 with a vacuum press apparatus. The resin film 108 is ABF (Ajinomoto Build-up Film), which is a film for forming insulation layer by AJINOMOTO CO., INC. Conditions for the vacuum pressing are, e.g., 100° C. and 1 MPa, which are the same as those for vacuum pressing the resin film 8 in the first embodiment. Thus, the resin film 108 of the resin film is formed on the resin layer 102 with the interconnections 104 and the conductor plugs 106 formed on.

Next, the resin layer 108 is solidified by thermal processing. Conditions for the thermal processing are the same as those for solidifying the resin layer 10 in the first embodiment, i.e., 170° C. and 1 hour.

Then, the surface part of the resin layer 108 and upper portion of the conductor plugs 106 are cut with the cutting tool. Conditions for cutting the surface part of the resin layer 108 and the upper portions of the conductor plugs 106 are the same as conditions for cutting the surface part of the resin layer 10 described above. That is, the rake angle of the cutting tool 12 is 0 degrees. The rotation number of the chuck table is, e.g., 1000 rpm. With such rotation number, the cut speed is about 5 m/second when the rotation radius is about 5 cm. The cut amount of the cutting tool 12 is, e.g., about 5 μm. The feed speed of the cutting tool 12 is, e.g., 50 μm/second. When cut under these conditions, the ten-point height of irregularities Rz of the surface of the resin layer 108 becomes, e.g., about 1-2 μm.

The ten-point height of irregularities Rz of the surface of the resin layer 108 is about 1-2 μm here but is not essentially about 1-2 μm. The surface of the resin layer 108 may be cut so that the ten-point height of irregularities Rz of the surface of the resin layer 108 is, e.g., 0.5-5 μm.

Then, a seed layer (not illustrated) is formed of copper or nickel on the entire surface by electroless plating. The method for forming the seed layer is the same as that for forming the seed layer 36 described in, e.g., the first embodiment. That is, after the conditioning, the adhesion of a catalyst to the surface of the resin layer, etc. are performed, the seed layer is formed by electroless plating.

Next, a photoresist film (not illustrated) is formed on the entire surface by spin coating.

Then, openings (not illustrated) are formed down to the seed layer by photolithography. The openings are for forming interconnections 110.

Next, the interconnections 110 are formed of Cu in the openings by electroplating. Then, the photoresist film is released.

Thus, the circuit board is fabricated by the circuit board fabrication method according to the present embodiment.

The circuit board according to the present embodiment is characterized mainly in that, as described above, the dielectric film 84 of the capacitors is formed of a resin sheet, and the surface part of the dielectric film 84 of the resin sheet is cut with a cutting tool.

In the conventional circuit board fabrication method, the resin layer must be subjected to the desmearing treatment. For the purpose of preventing the insulation between the upper electrodes and the lower electrodes from being impaired by ten-odd μm-pores formed in the desmearing treatment, the thickness of the resin layer must be set at 30 μm or above. Because the capacitance of a capacitor is in inverse proportion with the thickness of the dielectric film, it is difficult to fabricate a circuit board having a large capacitance.

In contrast to this, in the present embodiment, the dielectric film 84 is formed of a resin sheet, and the surface part of the dielectric film 84 of the resin sheet is cut with a cutting tool 12. According to the present embodiment, in which the surface of the dielectric film 84a after cut has suitable roughness, whereby the adhesion between the dielectric film 84a and the upper electrodes 90 can be ensured. In the present embodiment, which does not require the desmearing treatment, no excessively deep pores are formed in the surface of the dielectric film 84a. Accordingly, even when the film thickness of the dielectric film 84a is sufficiently small, the insulation between the upper electrodes 82 and the lower electrodes 90 can be sufficiently ensured. Thus, the present embodiment can fabricate the circuit board having high reliability and a capacitor of large capacitance.

### A THIRD EMBODIMENT

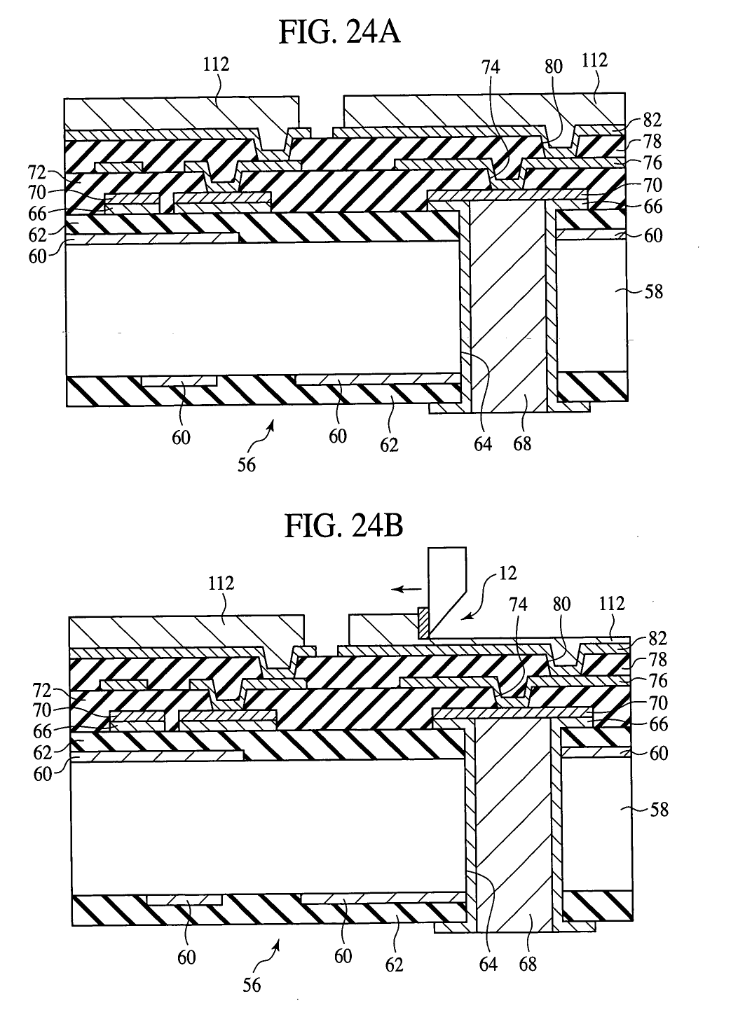

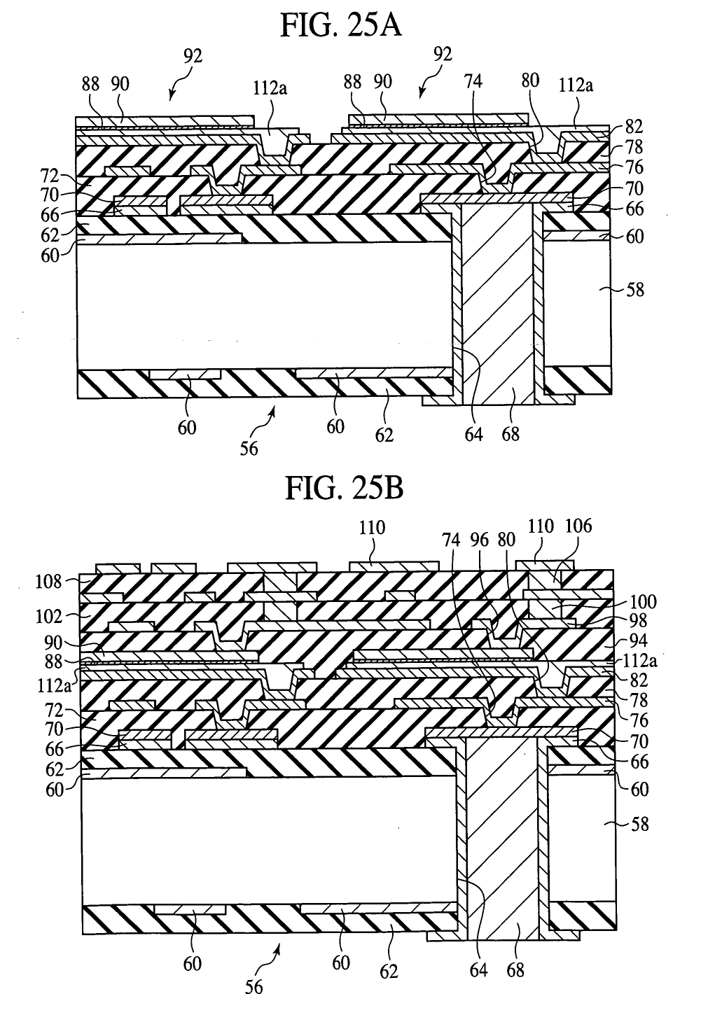

The circuit board fabrication method according to a third embodiment of the present invention will be explained with reference to FIGS. 24A to 25B. FIGS. 24A to 25B are sectional views of a circuit board in the steps of the circuit board fabrication method according to a third embodiment of the present invention. The same members of the present embodiments as those of the plating method and the semiconductor device fabrication method or the circuit board fabrication method according to the first or the second embodiment illustrated in FIGS. 1A to 23 are represented by the same reference numbers not to repeat or to simplify their explanation.

The circuit board fabrication method according to the present embodiment is characterized mainly in that a resistor layer forming resistor is formed of a resin film, and the surface part of the resistor layer is cut with a cutting tool.

First, the steps up to the step of forming electrodes 82 including the electrode forming steps are the same as those of the circuit board fabrication method according to the second embodiment described above with reference to FIGS. 14A to 16A, and their explanation will not be repeated.

Next, a resin film 112 is prepared. The resin film 112 is a resin film formed of a matrix of epoxy resin mixed with a filler of a conductor. The filler of a conductor is, e.g., the powder of nickel-chrome alloy.

The filler of a conductor is the powder of nickel-chrome alloy but is not essentially the powder of nickel-chrome alloy. A material whose magnetic permeability is higher than the resin of the matrix can be suitably used as the material of the filler. For example, the filler of a conductor may be the powder of carbon, the powder of silicon carbonate or others. The filler of a conductor may be a mixture of them.

Then, the resin films 112 are placed on a base substrate 58. At this time, the resin film 112 to be a resistor layer is spaced from the adjacent resin film 112 so as to prevent the electric short circuit between the resin films 112 to be resistor layers (see FIG. 24A).

Next, the resin film 112 is applied to the base substrate 58 by a vacuum press apparatus. Conditions for the vacuum pressing are, e.g., 100° C. and 1 MPa, which are the same as those for vacuum pressing the resin film 8 described in the first embodiment. Thus, the resistor layer 112 of the resin film is formed on the base substrate 58.

Next, thermal processing is performed to solidify the resin layer 112. Conditions for the thermal processing are the same as those for solidifying the resin layer 10 described in the first embodiment, i.e., 170° C. and 1 hour. This thermal processing is for solidifying the resin layer 112 itself. Thus, the thermal processing may be performed under the conditions described above for solidifying the resin layer 10.

Then, as illustrated in FIG. 24B, the surface of the resin layer 112 is cut with the cutting tool 12. Conditions for cutting the surface part of the resin layer 112 are the same as those for cutting the surface part of the resin layer 10. That is, the rake angle of the cutting tool 12 is 0 degrees. The rotation number of the chuck table is, e.g., about 1000 rpm. With the rotation number thus set, the cutting speed is about 5 m/second when the rotation radius is about 5 cm. The feed speed of the cutting tool 12 is, e.g., 50 μm/second. When the cut is performed under these conditions, the ten-point height of irregularities Rz of the surface of the resin layer 112a after cut is, e.g., about 1-2 μm. The conditions for cutting the surface of the resin layer 112 are suitably set, whereby the surface of the resin layer 112a after cut can be set at required roughness. In cutting the surface of the resin layer 112, the surface of the resin layer 112 is cut until the thickness of the resin layer 112 present on the electrodes 82 becomes, e.g., 10 μm. Thus, the resistor layer 112a formed of the resin layer of, e.g., a 10 μm-thickness is formed.

The ten-point height of irregularities Rz of the surface of the resin layer 112a is about 1-2 μm here but is not essentially limited to about 1-2 μm. The surface of the resin layer 112a may be cut so that the ten-point height of irregularities Rz of the surface of the resin layer 112a becomes, e.g., 0.5-5 μm.

Next, a seed layer (not illustrated) is formed on the resistor layer 112a by electroless plating. The method for forming the seed layer is the same as for forming the seed layer 36 described in, e.g., the first embodiment. That is, after the conditioning, the adhesion of a catalyst to the surface of the resin layer, the seed layer is formed by electroless plating.

Next, a photoresist film (not illustrated) is formed on the entire surface by spin coating.

Then openings (not illustrated) are formed down to the seed layer by photolithography. The openings are for forming electrodes 90.

Next, the electrodes 90 of Cu are formed in the openings by electroplating. Then, the photoresist film is released.

Next, the exposed parts of the seed layer are etched off. Thus, resistors 112a of the resin are formed between the electrodes 82 and the electrodes 90.

The following steps of the circuit board fabrication method are the same as those of the circuit board fabrication method according to the second embodiment illustrated in FIGS. 20B to 23 will not be explained.

The circuit board of the present embodiment is characterized mainly in that the resistor layer 112 forming the resistors is formed of the resin film, and the surface part of the resistor layer 112 is cut.

In the present embodiment, the surface part of the resistor layer 112 of a resin is cut, so that the surface of the resistor layer 112a after cut has suitable roughness. Accordingly, the resistor layer 112a and the electrodes 90 can have sufficient adhesion. In the present embodiment, which does not require the desmearing treatment, excessively deep pores are not formed in the resistor layer 112a of a resin. Thus, even when the thickness of the resistor layer 112a is small, the insulation between the electrode 82 and the electrodes 90 can be sufficiently ensured. The thickness of the resistor layer 112a is suitably set, whereby the resistance value can be set at a required value. Excessively deep pores are not formed in the surface of the resistor layer 112a, which makes the dispersion of the resistance value small. Thus, in the present embodiment, it is possible to fabricate circuit boards including resistors of high reliability.

### A FOURTH EMBODIMENT

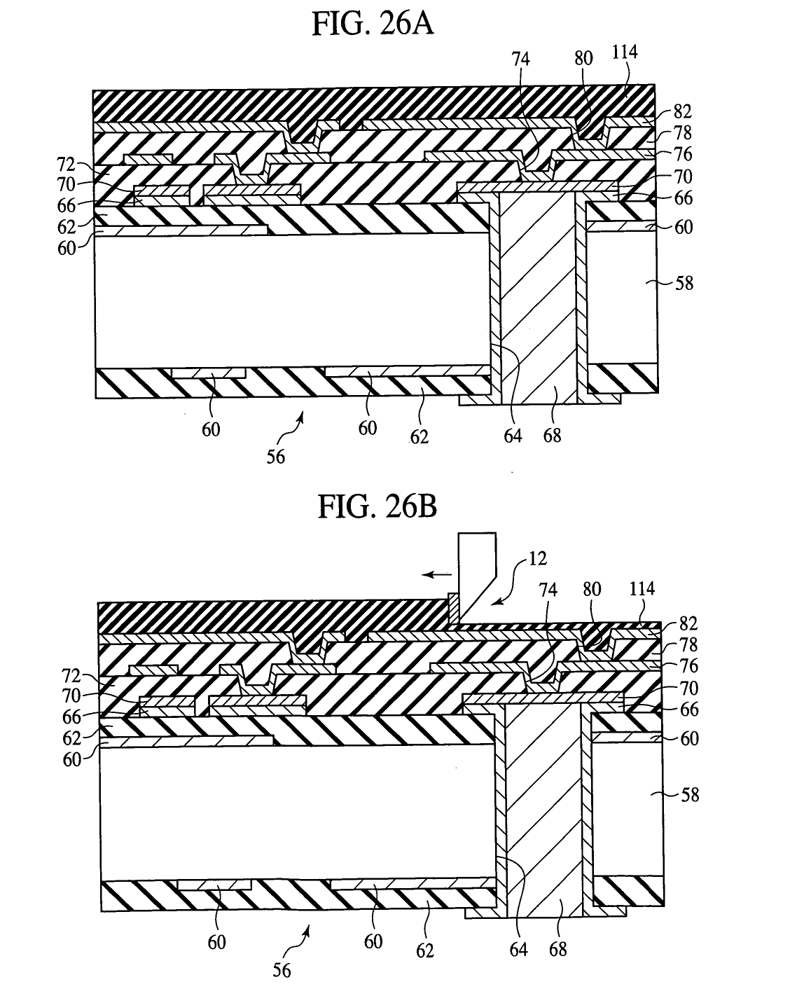

The circuit board fabrication method according to a fourth embodiment will be explained with reference to FIGS. 26A to 28. FIGS. 26A to 28 are sectional views of a circuit board in the steps of the circuit board fabrication method according to the present embodiment, which illustrate the method. The same members of the present embodiment as those of the plating method, the semiconductor device fabrication method and the circuit board fabrication method according to the first to the third embodiments illustrated in FIGS. 1A to 25B are represented by the same reference numbers not to repeat or to simplify their explanation.

The circuit board fabrication method according to the present embodiment is characterized mainly in that a high magnetic permeability layer 114 is formed of a resin film, and then the surface part of the high magnetic permeability layer 114 is cut, and next, an inductor 116 is formed on the high magnetic permeability layer 114a.

The steps up to the step of forming electrodes 82 including the electrodes forming step are the same as those of the circuit board fabrication method according to the second embodiment described above with reference to FIGS. 14A to 16A, and their explanation will be omitted.

Next, a resin film 114 is prepared. The resin film 114 is a resin film formed of a matrix of epoxy resin containing a filler of a magnetic permeability higher than that of the resin. The high-magnetic permeability filler is, e.g., Mn—Zn-based ferrite.

The high-magnetic permeability filler is the powder of Mn—Zn-based ferrite here but is not limited to the powder of Mn—Zn-based ferrite. A material of high magnetic permeability higher than that of the resin of the matrix can be suitably used as a material of the filler. For example, the powder of Ni—Zn-based ferrite may be used as the material of the filler. A mixture of them may be used as the filler.

The magnetic permeability of epoxy resin forming the matrix is about 1. The magnetic permeability of Mn—Zn-based ferrite is about 10. The magnetic permeability of Ni—Zn-based ferrite is about 20. A filler of such high magnetic permeability is contained in the resin, whereby the resin film 114 can have high magnetic permeability.

Next, the resin film 114 is placed on a base substrate 58.

Next, the resin film 114 is applied to the base substrate 58 with a vacuum press apparatus. Conditions for the vacuum pressing are the same as those for vacuum pressing the resin film 8 in the first embodiment, e.g., 100° C. and 1 MPa. Thus, the high-magnetic permeability layer 114 of the resin film is formed on the base substrate 58 (see FIG. 26A).

Next, thermal processing is performed to solidify the resin layer 114. Conditions for the thermal processing are the same as those for solidifying the resin layer 10 in the first embodiment, e.g., 170° C. and 1 hour. This thermal processing is for solidifying the resin layer 114 itself. Accordingly, the thermal processing may be performed under the same conditions as those for solidifying the resin layer 10.

Then, as illustrated in FIG. 26B, the surface of the resin layer 114 is cut with the cutting tool 12. Conditions for cutting the surface part of the resin layer 114 are the same as those for cutting the surface part of the resin layer 10. That is, the rake angle of the cutting tool 12 is 0 degrees. The rotation number of the chuck table is, e.g., about 1000 rpm. With the rotation number thus set, the cutting speed is about 5 m/second when the rotation radius is about 5 cm. The feed speed of the cutting tool 12 is, e.g., 50 μm/second. When the cut is performed under these conditions, the ten-point height of irregularities Rz of the surface of the resin layer 114a after cut is, e.g., about 1-2 μm. The conditions for cutting the surface part of the resin layer 114a are suitably set, whereby the surface of the resin layer 114a after cut can be set at required roughness. Thus, the high-magnetic permeability layer 114a of the resin of, e.g., a 10 μm is formed.

The ten-point height of irregularities Rz of the surface of the resin layer 114a is about 1-2 μm here but is not essentially limited to about 1-2 μm. The surface of the resin layer 114a may be cut so that the ten-point height of irregularities Rz of the surface of the resin layer 114a becomes, e.g., 0.5-5 μm.

Next, a seed layer (not illustrated) of copper or nickel is formed on the entire surface by electroless plating. The method for forming the seed layer is the same as for forming the seed layer 36 in, e.g., the first embodiment. That is, after the conditioning, the adhesion of a catalyst to the surface of the resin layer, the seed layer is formed by electroless plating.

Next, a photoresist film (not illustrated) is formed on the entire surface by spin coating.

Then, the photoresist film is patterned by photolithography to form openings (not illustrated) for forming the inductor 116 and an interconnection 118.

Then, Cu is applied in the openings of the photoresist film by electroplating to form the inductor 116 and the interconnection 118.

Then, the photoresist film is released, and the exposed parts of the seed layer is etched off.

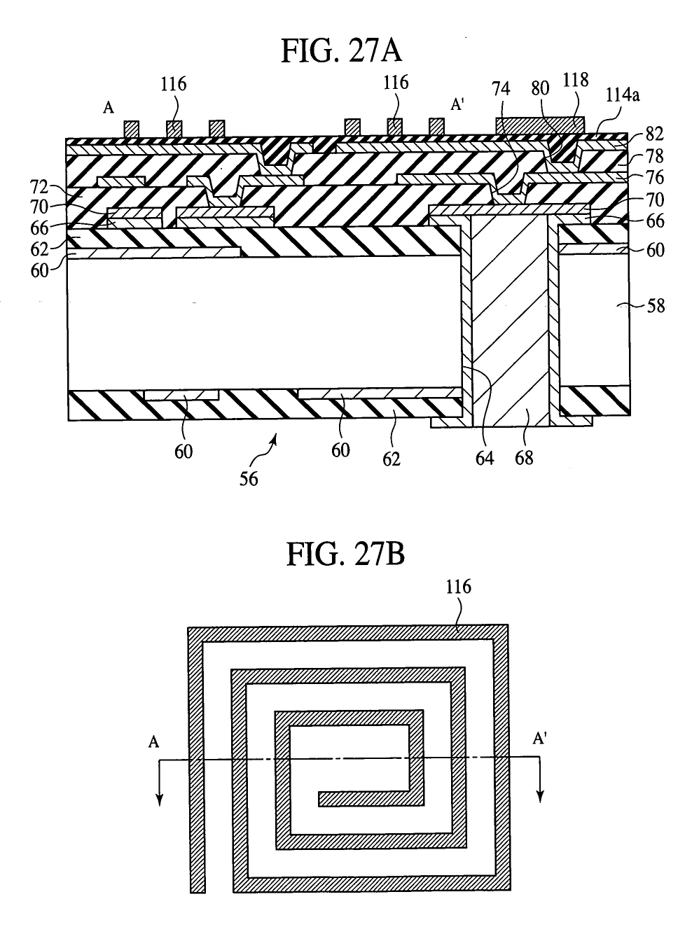

Thus, as illustrated in FIGS. 27A and 27B, the inductor 116 in the shape of a plane coil and the interconnection 118 are formed on the high-magnetic permeability layer 114a of the resin. In place of the above-described selective plating, the inductor 116 and the interconnection 118 can be formed by forming a Cu layer on the entire seed layer first electroplating and then selectively etching the Cu layer.

FIG. 27B illustrates a plan shape of the inductor on the circuit board of the present embodiment, and FIG. 27A is the sectional view along the line A-A′ in FIG. 27B.

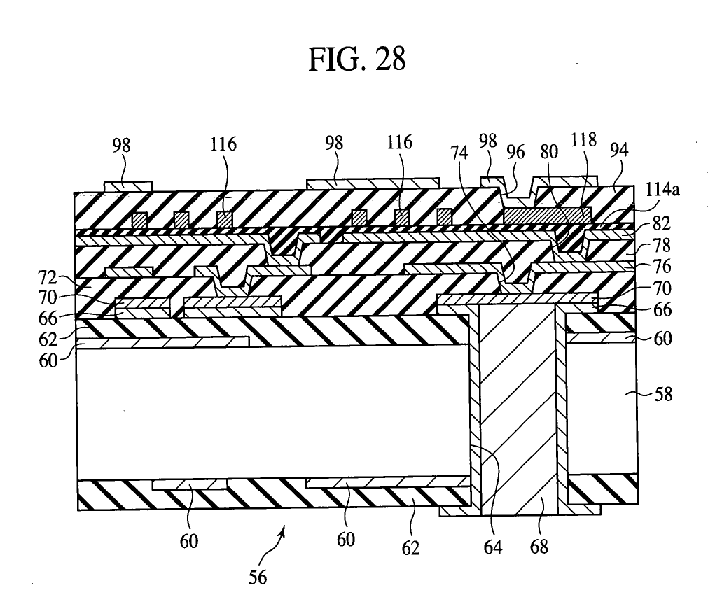

Next, as illustrated in FIG. 28, the resin film 94 is applied to the substrate with a vacuum press apparatus. The resin film 94 is ABF (Ajinomoto Build-up Film), which is a film for forming insulation films by AJINOMOTO CO., INC. The thickness of the resin film 94 is 60 μm. Conditions for the vacuum pressing are, e.g., 100° C. and 1 MPa, which are the same as those for vacuum pressing the resin film 10 in the first embodiment. Thus, the resin layer 94 is formed of the resin film on the base substrate 58.

Thermal processing is performed to solidify the resin layer 94. Conditions for the thermal processing are the same as those for solidifying the resin layer 10 described in the first embodiment, e.g., 170° C. and 1 hour.

Then, the surface of the resin layer 94 is cut with the cutting tool 12. Conditions for cutting the surface part of the resin layer 94 are the same as those for cutting the surface part of the resin layer 10. That is, the rake angle of the cutting tool 12 is 0 degrees. The rotation number of the chuck table is, e.g., about 1000 rpm. With the rotation number thus set, the cutting speed is about 5 m/second when the rotation radius is about 5 cm. The feed speed of the cutting tool 12 is, e.g., 50 μm/second. When the cut is performed under these conditions, the ten-point height of irregularities Rz of the surface of the resin layer 94 after cut is, e.g., about 1-2 μm.

The ten-point height of irregularities Rz of the surface of the resin layer 94 is about 1-2 μm here but is not essentially limited to about 1-2 μm. The surface of the resin layer 94 may be cut so that the ten-point height of irregularities Rz of the surface of the resin layer 94 becomes, e.g., 0.5-5 μm.

A contact hole 96 is formed in the resin layer 94 down to the interconnection 118 by photolithography.

Next, a seed layer (not illustrated) of copper or nickel is formed on the entire surface by electroless plating. The method for forming the seed layer is the same as for forming the seed layer 36 described in, e.g., the first embodiment. That is, after the conditioning, the adhesion of a catalyst to the surface of the resin layer, the seed layer is formed by electroless plating.

Next, a photoresist film (not illustrated) is formed on the entire surface by spin coating.

Then, openings (not illustrated) are formed down to the seed layer by photolithography. The openings are for forming interconnections 98.

Then, the interconnections 98 of Cu are formed in the openings by electroplating. Then, the photoresist film is released.

Next, the exposed parts of the seed layer are etched off (see FIG. 28).

The following steps of the circuit board fabrication method according to the present embodiment are the same as those of the circuit board fabrication method according to the second embodiment, and their explanation will be omitted.

The circuit board fabrication method according to the present embodiment is characterized mainly in that the high-magnetic permeability layer 114 is formed of the resin film, then the surface part of the high-magnetic permeability layer 114 is cut with the cutting tool 12, and then the inductor 116 is formed on the high-magnetic permeability layer 114a.

In the present embodiment, the surface part of the high-magnetic permeability layer 114 of the resin film is cut with the cutting tool 12, whereby the surface of the high-magnetic permeability layer 114a after cut has suitable roughness. Accordingly, the adhesion between the high-magnetic permeability layer 114a of the resin layer and the inductor 116 can be sufficiently ensured. The present embodiment does not require the desmearing treatment, and accordingly, excessively deep pores are not formed in the surface of the high-magnetic permeability layer 114a of the resin, which permits a micronized pattern of a photoresist film to be formed on the high-magnetic permeability layer 114a. Thus, according to the present embodiment, the inductor 116 can have high reliability and a very small coil pitch.

### MODIFIED EMBODIMENTS

The present invention is not limited to the above-described embodiments and can cover other various modifications.

For example, in the above-described embodiments, the seed layer is formed by electroless plating but may be formed by sputtering. The resin layer is cut with a cutting tool to give suitable roughness to the surface of the resin layer, which sufficiently ensures the adhesion between the resin layer and the seed layer, even when the seed layer is formed by sputtering. Thus, even when the seed layer is formed by sputtering, the adhesion between the resin layer and the plating film can be sufficiently ensured.

What is claimed is:

1. A plating method comprising the steps of:
forming a resin layer over a base substrate;
cutting the surface part of the resin layer with a cutting tool so that a ten-point height of irregularities of the surface of the resin layer is 0.5-5 μm;
forming a seed layer on the resin layer; and
forming a plating film on the seed layer by electroplating.

2. A plating method according to claim 1, wherein
in the step of forming the resin layer, a resin sheet is applied to the base substrate to form the resin layer of the resin sheet.

3. A plating method according to claim 1, wherein
the cutting tool is formed of diamond.

4. A plating method according to claim 1, wherein
in the step of forming a seed layer, the seed layer is formed by electroless plating or sputtering.

5. A plating method according to claim 1, wherein
a thickness of the resin layer is larger than a difference of a maximum value and a minimum value of a intra-plane thickness of the base substrate.

6. A plating method according to claim 1, wherein
the seed layer is formed of copper or nickel.

7. A semiconductor device fabrication method comprising the steps of:
forming a resin layer over a semiconductor substrate;
cutting the surface part of the resin layer with a cutting tool so that a ten-point height of irregularities of the surface of the resin layer is 0.5-5 μm;
forming a seed layer on the resin layer; and
forming on the seed layer an interconnection of a plating film by electroplating.

8. A semiconductor device fabrication method according to claim 7, which further comprises, before the step of forming a resin layer,
the step of forming a conductor plug over the semiconductor substrate, and in which
in the step of forming the resin layer, the resin layer is formed, burying the conductor plug,
in the step of cutting the surface part of the resin layer, the upper portion of the conductor plug is cut with the cutting tool, and
in the step of forming a seed layer, the seed layer is formed on the conductor plug.

9. A circuit board fabrication method comprising the steps of:
forming a resin layer over a base substrate;
cutting the surface part of the resin layer with a cutting tool so that a ten-point height of irregularities of the surface of the resin layer is 0.5-5 μm;
forming a seed layer on the resin layer; and
forming an interconnection on the seed layer by electroplating.

10. A circuit board fabrication method for fabricating a circuit board including a base substrate; and a capacitor having a lower electrode formed over the base substrate, a dielectric film formed over the lower electrode, and an upper electrode formed over the dielectric film, the method comprising the steps of:
forming the lower electrode over the base substrate;
forming the dielectric film containing a resin over at least the lower electrode;
cutting with a cutting tool the surface part of the dielectric film so that a ten-point height of irregularities of the surface of the dielectric film is 0.5-5 μm;
forming a seed layer on the dielectric film; and
forming the upper electrode on the seed layer by electroplating.

11. A circuit board fabrication method according to claim 10, wherein
in the step of cutting the surface part of the dielectric film, the surface part of the dielectric film is cut so that a thickness of the dielectric film present over the lower electrode is 5 μm or below.

12. A circuit board fabrication method according to claim 10, wherein
the dielectric film further contains a filler of a material whose specific dielectric constant is higher than that of the resin.

13. A circuit board fabrication method according to claim 12, wherein
the filler is any one of CaTiO₃, BaTiO₃, SrTiO₃, ZnTiO₃, PbTiO₃, CaZrO₃, BaZrO₃, PbZrO₃, Ba_{X}Sr_{1-X}TiO₃, BaTi_{X}Zr_{1-X}O₃, PbZr_{X}Ti_{1-X}O₃, Pb_{X}La_{1-X}Zr_{Y}Ti_{1-Y}O₃, La₂Ti₂O₇ and Nd₂Ti₂O₇, or a mixture of them.

14. A circuit board fabrication method for fabricating a circuit board including a base substrate; a first electrode formed over the base substrate; and a resistor formed over the first electrode; and a second electrode formed over the resistor, the method comprising the steps of:
forming the first electrode on the base substrate;
forming a resistor layer containing the resin over the first electrode;
cutting the surface part of the resistor layer so that a ten-point height of irregularities of the surface of the resistor layer is 0.5-5 μm;
forming a seed layer on the resistor layer; and
forming an electrode on the seed layer by electroplating.

15. A circuit board fabrication method according to claim 14, wherein
the resistor layer contains a filler of a conductor.

16. A circuit board fabrication method according to claim 15, wherein
the filler is formed of any one of carbon, silicon carbonate and nickel-chrome alloy, or a mixture of them.

17. A circuit board fabrication method for fabricating a circuit board including a base substrate and an inductor formed over the base substrate, the method comprising the steps of:
forming an insulation layer containing a resin over the base substrate;
cutting the surface part of the insulation layer with a cutting tool so that a ten-point height of irregularities of the surface of the insulation layer is 0.5-5 μm;
forming a seed layer on the insulation layer, and
forming the inductor on the seed layer by electroplating.

18. A circuit board fabrication method according to claim 17, wherein
the insulation layer further contains a filler of a material whose magnetic permeability is higher than that of the resin.

19. A circuit board fabrication method according to claim 18, wherein
the filler is formed of any one of Mn—Zn-based ferrite and Ni—Zn-based ferrite, or a mixture of them.
